(19) United States
(12) Patent Application Publication
(10) Pub. No.: US 2007/0153308 A1
(43) Pub. Date: Jul. 5, 2007

(54) Apparatus and Method for Reducing Ink/ Toner Consumption of Color Printers

(76) Inventors: Reuven Zemach, Petach Tikva (IL); Ben Zion Shaich, Zikhron Ya'aqov (IL)

Correspondence Address: FLEIT KAIN GIBBONS GUTMAN BONGINI & BIANCO, 21355 EAST DIXIE HIGHWAY, SUITE 115, MIAMI, FL, 33180, US

(21) Appl. No.: 11/559,587

(22) Filed: Nov. 14, 2006

Related U.S. Application Data
(60) Provisional application No. 60/735,866, filed on Nov. 14, 2005.

(51) Int. Cl. G03F 3/08

(52) U.S. Cl. 358/1.9; 358/518

(57) ABSTRACT

Disclosed are methods for ink/toner saving including an ink/toner consumption controller which processes input image data via computer vision (CV) filtering models and other approaches to generate printable raster graphic, vector graphic and font character data on CMYK printing devices. User preferences may be specified using a GUI application. The ink/toner consumption controller manipulates the saving of colorent using dedicated techniques adopted for each type of document object. Models of color human perception are used for the combinations of the required percentages of a printer's CMYK ink/toner. These models are implemented by methods of CV selection rules for preferred objects and image areas, such as human faces, human skin and ROI, for maintaining maximum adherence to original image data. A color balancing method is used to ensure that CMY stacks consumptions are maintained similar throughout their usage. Additionally, methods are applied to compensate for missing CMYK colorants.

### CROSS REFERENCE TO RELATED APPLICATION

This application claims the benefit under 35 U.S.C. § 119(e) of Provisional Application No. 60/735,866, filed Nov. 14, 2005. The entire contents of this provisional patent application are incorporated herein by reference.

### FIELD OF THE INVENTION

The present invention generally relates to systems and methods for managing, controlling and saving color printing with color printer device; more particularly it relates to systems and method which balance and reduce ink/toner consumption according to analysis of color perception and computer vision.

### BACKGROUND

In typical printing procedure, ink/toner particles are deposited on the surface of a medium, such as a paper, using respective amounts of cyan, magenta, yellow and black (CMYK). In color printing, cyan, magenta, and yellow (CMY) are considered primary colors in the subtractive color system. These colors function as the process-colors in the heavy printing industry; they are also used in home/office inkjet/laser printer technology. Many of the software applications today are generally supplied with tools to produce color document output incorporating images, characters, graphics and the like, into image-pixels-data format. This type of use usually results in an increase of ink/toner color consumption even in cases where much of the document is in black and white.

Known in the art are several solutions for reducing the color ink/toner consumption of color printers. The related-art color printer apparatuses may use particular methods to skip dots printing by use of a selection mask pattern, thereby reducing ink/toner colorant amounts applied to the printed document. For instance, Japanese Patent Application No. 11-112789 uses a technique of purging data at every other pixel in the image-pixels-data representing a document, and prints the resultant document image data subtracted with the purged image data, reducing the number of actually printed pixels, thereby decreasing toner amounts.

Another print saving method in which a mode can be chosen from a plurality of modes is presented in the following patents and patent applications: Japanese Patent Application No. 2001-130055 which includes several printing levels, a toner saving mode, a high picture quality mode, and so on. The user can select the level of quality by switching from the toner saving mode to the high picture quality mode, and so on. U.S. Pat. No. 6,236,817 discloses a technique that uses under color tables for a toner saving mode, for outputting an under color concentration value printing a color image on a recording medium with the concentration of developer per color when selecting between one of the non-toner saving mode and the toner saving mode. U.S. Pat. No. 6,313,925 discloses a technique for converting from three colorants to four or more colorants. Table of patches of varying combinations of CMYK is used for maximum black substitution at given percentage of Under Color Addition (UCA) yielding maximum printed quality.

The ink/toner saving related-art technologies described above have several shortcomings. First, they refer to colorants saving over the entire image, graphics, characters and so on, of a printed document. These solutions provide results of overwhelming faint colors where differential ink/toner colorants saving is not applied due to difficulties of processing speed, problems to maintain human color perception adherence and so on.

Second, the ink/toner saving related-art technologies described above are not capable for differential ink/toner saving in an image-pixels-data of a document, that includes letters, graphics, and images as previously described. These documents contain parts of the original image-pixels-data that may need lower printing quality with fewer amounts of ink/toner colorants, while other parts of the original image-pixels-data may need higher printing quality.

There is therefore a need for apparatuses and methods for ink/toner print saving, controlling and managing which may satisfy differential ink/toner colorants saving to perform fast selective color-processing that operates in accordance with color human perception in the printed document. Such a solution should support differential ink/toner saving methods, in addition to the existing printing stages, to achieve high efficient results for printing the different parts of the original image-pixels-data. In this regard, color printing apparatus and methods for ink/toner saving, controlling and managing is needed to achieve printing results to be managed and controlled at differential levels in color-processing applied to the original image-pixels-data according to automated or manual selection rules. Thus, substantial difficulties and limitations of the related art in ink/toner saving may be eradicated.

### SUMMERY OF THE INVENTION

Disclosed is a method for saving colorant particles of a printing device during a printing procedure of a document. The method comprises the following steps: identifying segments of the document according to object types; processing each object type of document in accordance with the object attributes and identified characteristics of the object; adjusting said processing in accordance with Computer Vision (CV) and image processing techniques of filtering modules; and applying transformation of printing color characteristics on at least one object in the document. The transformation is applied in accordance with predefined rules and identified characteristics of each object. The object types optionally include at least one of the following: binary images, piecewise-constant images, photograph images, vector graphic, vector font, bitmaps font.

The disclosed method may also comprise the step of tracking usage of colorant and balancing their consumption at lined-out level for reaching maximum parallel utilization. Optionally, the method may include the steps of checking availability of colorants in the printing device and using existing colorants to fill-in for missing colorants. The method may also include the step of converting grayscale segments of the document from colorants to black pigments using grey component replacement (GCR) methods. The GCR method is optionally within the range between maximum GCR and non-GCR. The method optionally also includes the step of performing at least one of the following procedures: adoptive separation procedures, differential colorants saving procedure in said document applying CV and image processing generated modules.

The printing procedure is optionally performed by identifying regions of interest (ROI). The method may also include the step of masking segments in the document. The identification is optionally preformed according to predefined classification of the attributes of regions within the document, distinguishing between image and background sections and/or by identifying preferred objects in said document. Then colorant saving techniques are applied to segments of the document which are outside of the ROI. The identification between sections is performed automatically or according to user preferences as defined by the user using a graphic user interface (GUI).

A dedicated color perception process based on bordering effect which maintains visual intensity perception in response to illumination may be utilized. The method is applied with respect to the various hues of the component colors.

The method may also include the steps of evaluating levels of K-component in comparison to CMY-components in regions which combine K-component and CMY-components and reducing CMY consumption when K-component levels are dominant. Adaptive proportional linear K-consumption may be selected with respect to the original component-level and the CMY color channel may be compressed according to their hues using varying quantization levels per pixel.

The disclosed method may be implemented in software or in an independent hardware component.

### BRIEF DESCRIPTION OF THE DRAWINGS

The subject matter regarded as the invention will become more clearly understood in light of the ensuing description of embodiments herein, given by way of example and for purposes of illustrative discussion of the present invention only, with reference to the accompanying drawings, wherein

FIG. 1 is a schematic illustration of a figure mapped onto three-dimensional space: x, y and z in accordance with preferred embodiments of the present invention;

FIG. 2 is a schematic illustration of the ink/toner saving apparatus in hardware configuration in accordance with preferred embodiments of the present invention;

FIG. 3 is a schematic illustration of the ink/toner saving apparatus in software configuration in accordance with preferred embodiments of the present invention;

FIG. 4 is the description of the main block diagram of processing fonts, raster graphics and font objects of input document for carrying out ink/toner saving and balancing in accordance with preferred embodiments of the present invention;

FIG. 5 is a descendent-block diagram describing the processing of bitmap font and vector font objects for carrying out ink/toner saving and balancing in accordance with preferred embodiments of the present invention;

FIG. 6 is a descendent-block diagram illustrating the algorithm of processing piecewise constant image for carrying out ink/toner saving and balancing for various amounts of ink/toner cartridge contents (empty/available) in accordance with preferred embodiments of the present invention;

FIG. 7 is a descendent-block diagram illustrating the algorithm of processing binary image for carrying out ink/toner saving and balancing for various amounts of ink/toner cartridge contents (empty/available) in accordance with preferred embodiments of the present invention;

FIG. 8 is a descendent-block diagram illustrating the algorithm of processing photo image objects for carrying out ink/toner saving and balancing for various amounts of ink/toner cartridge contents (empty/available) in accordance with preferred embodiments of the present invention;

FIG. 9 is a descendent-block diagram illustrating the algorithm of processing vector graphic objects, for carrying out ink/toner saving and balancing for various amounts of ink/toner cartridge contents (empty/available) in accordance with preferred embodiments of the present invention;

FIG. 10 is a descendent-block diagram illustrating the algorithm of processing bitmap font objects for carrying out ink/toner saving and balancing for various amounts of ink/toner cartridge contents (empty/available) in accordance with preferred embodiments of the present invention;

FIG. 11 is a descendent-block diagram illustrating the algorithm of processing vector font objects for carrying out ink/toner saving and balancing for various amounts of ink/toner cartridge contents (empty/available) in accordance with preferred embodiments of the present invention;

FIG. 12 illustrates the algorithm which is performed when printing with empty K-ink/K-toner cartridges for processing raster graphics in accordance with preferred embodiments of the present invention;

FIG. 13 illustrates the algorithm which is performed when printing with empty K-ink/K-toner cartridges for processing vector graphics in accordance with preferred embodiments of the present invention;

FIG. 14 illustrates the algorithm which is performed when printing with empty K-ink/K-toner cartridges for processing font objects in accordance with preferred embodiments of the present invention;

FIG. 15 illustrates the algorithm which enables ink/toner saving and printing whenever only one of the CMY ink/toner components is absent, for processing raster graphics in accordance with preferred embodiments of the present invention;

FIG. 16 illustrates the algorithm which enables ink/toner saving and printing whenever only one of the CMY ink/toner components is absent, for processing vector graphics in accordance with preferred embodiments of the present invention;

FIG. 17 illustrates the algorithm which enables ink/toner saving and printing whenever only one of the CMY ink/toner components is absent, for processing font objects in accordance with preferred embodiments of the present invention;

FIG. 18 illustrates the algorithm for carrying out ink/toner saving and balancing, whenever only one of the ink/toner CMY-components is absent, for processing raster graphics in accordance with preferred embodiments of the present invention;

FIG. 19 illustrates the algorithm for carrying out ink/toner saving and balancing, whenever only one of the ink/toner CMY-components is absent, for processing vector graphics in accordance with preferred embodiments of the present invention;

FIG. 20 illustrates the algorithm for carrying out ink/toner saving and balancing, whenever only one of the ink/toner CMY-components is absent, for processing font objects in accordance with preferred embodiments of the present invention;

FIG. 21 illustrates the algorithm which enables printing and removing color artifacts when only one of the ink/toner CMY-components is absent, for processing raster graphics in accordance with preferred embodiments of the present invention;

FIG. 22 illustrates the algorithm which enables printing and removing color artifacts when only one of the ink/toner CMY-components is absent, for processing vector graphics in accordance with preferred embodiments of the present invention;

FIG. 23 illustrates the algorithm which enables printing and removing color artifacts when only one of the ink/toner CMY-components is absent, for processing font objects in accordance with preferred embodiments of the present invention;

FIG. 24 illustrates the algorithm which enables ink/toner saving and printing whenever only one of the ink/toner CMY-components is absent, for processing raster graphics in accordance with preferred embodiments of the present invention;

FIG. 25 illustrates the algorithm which enables ink/toner saving and printing whenever only one of the ink/toner CMY-components is absent, for processing vector graphic in accordance with preferred embodiments of the present invention;

FIG. 26 illustrates the algorithm which enables ink/toner saving and printing whenever only one of the ink/toner CMY-components is absent, for processing font objects in accordance with preferred embodiments of the present invention;

FIG. 27 illustrates the algorithm which enables ink/toner K-color component saving and printing whenever all CMY-components are absent, for processing raster graphic in accordance with preferred embodiments of the present invention;

FIG. 28 illustrates the algorithm which enables ink/toner K-color component saving and printing whenever all CMY-components are absent, for processing vector graphic in accordance with preferred embodiments of the present invention;

FIG. 29 illustrates the algorithm which enables ink/toner K-color component saving and printing whenever all CMY-components are absent, for processing font objects in accordance with preferred embodiments of the present invention;

FIG. 30 is an illustration of the algorithm for replacing colors of bitmap fonts for saving and balancing their foreground and background colors in accordance with preferred embodiments of the present invention;

FIG. 31 is an illustration of the algorithm for replacing colors of vector fonts for saving and balancing their foreground and background colors in accordance with preferred embodiments of the present invention;

FIG. 32 illustrates the algorithm for saving and balancing ink/toner colors in font objects in accordance with preferred embodiments of the present invention;

FIG. 33 illustrates the algorithm for performing the replacement of colors of vector graphic objects for saving and balancing their colors in accordance with preferred embodiments of the present invention;

FIG. 34 is a graphic illustration of the process of finding the boundary lines of the objects and setting their colors as the original object colors in accordance with preferred embodiments of the present invention;

FIG. 35 is an illustration of the algorithm for saving and balancing ink/toner colors in vector graphic objects in accordance with preferred embodiments of the present invention;

FIG. 36 illustrates the algorithm for mask calculations in photo images in accordance with preferred embodiments of the present invention;

FIG. 37 is an example for the processes of performing mask calculations in accordance with preferred embodiments of the present invention;

FIG. 38 is an illustration of the algorithm for the classification of raster images to the classes of binary images, piecewise constant images or photo images in accordance with preferred embodiments of the present invention;

FIG. 39 is an illustration of the algorithm for checking whether the input raster image is a binary one in accordance with preferred embodiments of the present invention;

FIG. 40 is an illustration of the algorithm for checking whether the input raster image is either a piecewise image or a photo image in accordance with preferred embodiments of the present invention;

FIG. 41 is an exemplary illustration of the process of image saving without balancing in accordance with preferred embodiments of the present invention;

FIG. 42 is an illustration of the algorithm for the processing of binary image objects, for carrying out ink/toner saving and balancing in accordance with preferred embodiments of the present invention;

FIG. 43 is an illustration of the algorithm for the processing of photo image objects, for carrying out ink/toner saving and balancing in accordance with preferred embodiments of the present invention;

FIG. 44 is a schematic graph illustrating how the “bordering effect” is used for purposes of K-component ink/toner saving in accordance with preferred embodiments of the present invention;

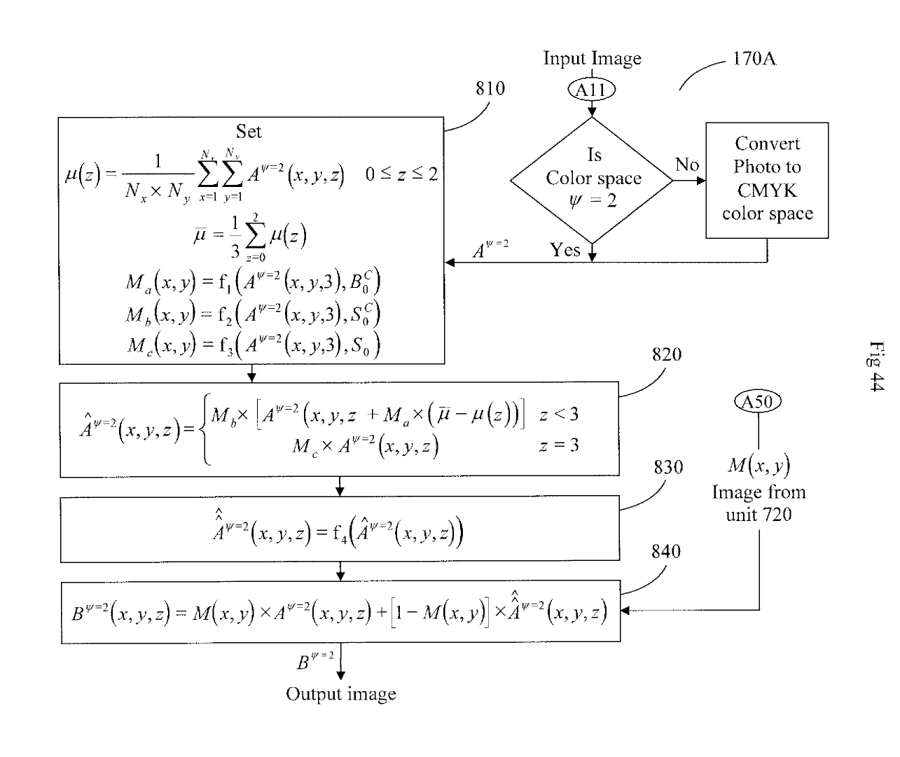

FIG. 45 is an illustration of the scheme of bordering effect in accordance with preferred embodiments of the present invention;

The drawings together with the description make apparent to those skilled in the art how the invention may be embodied in practice.

No attempt is made to show structural details of the invention in more detail than is necessary for a fundamental understanding of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PREFERRED EMBODIMENTS

The preferred embodiments of the present invention provide effective apparatus and methods for an ink/toner saving system. The system includes a color-balancing controller that processes input image data via computer vision (CV) filtering models. The system also includes masking and additional approaches for generating printable images, art-line and character data, and a cyan, magenta, yellow and black (CMYK) feedback ink/toner consumption log-information. The invention enables setting a virtual backward-image calibrated data processing for printing options with reference to the current stack-colorant status through an automatic decision-making module. This module ensures maintaining maximum compatibility with the original color level images, graphics and characters, enabling the automatic switch to one of the alternatives, while allowing performing adjustments in the preferred decision when needed.

An embodiment is an example or implementation of the inventions. The various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “one embodiment”, “an embodiment”, “some embodiments” or “other embodiments” means that a particular feature, structure, or characteristic described in connection with the embodiments is included in at least one embodiments, but not necessarily all embodiments, of the inventions. It is understood that the phraseology and terminology employed herein is not to be construed as limiting and are for descriptive purpose only.

The principles and uses of the teachings of the present invention may be better understood with reference to the accompanying description, figures and examples. It is to be understood that the details set forth herein do not construe a limitation to an application of the invention. Furthermore, it is to be understood that the invention can be carried out or practiced in various ways and that the invention can be implemented in embodiments other than the ones outlined in the description below.

It is to be understood that the terms “including”, “comprising”, “consisting” and grammatical variants thereof do not preclude the addition of one or more components, features, steps, or integers or groups thereof and that the terms are to be construed as specifying components, features, steps or integers. The phrase “consisting essentially of”, and grammatical variants thereof, when used herein is not to be construed as excluding additional components, steps, features, integers or groups thereof but rather that the additional features, integers, steps, components or groups thereof do not materially alter the basic and novel characteristics of the claimed composition, device or method.

If the specification or claims refer to “an additional” element, that does not preclude there being more than one of the additional element. It is to be understood that where the claims or specification refer to “a” or “an” element, such reference is not be construed that there is only one of that element. It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks. The term “method” refers to manners, means, techniques and procedures for accomplishing a given task including, but not limited to, those manners, means, techniques and procedures either known to, or readily developed from known manners, means, techniques and procedures by practitioners of the art to which the invention belongs. The descriptions, examples, methods and materials presented in the claims and the specification are not to be construed as limiting but rather as illustrative only.

Meanings of technical and scientific terns used herein are to be commonly understood as by one of ordinary skill in the art to which the invention belongs, unless otherwise defined. The present invention can be implemented in the testing or practice with methods and materials equivalent or similar to those described herein.

The terms “bottom”, “below”, “top” and “above” as used herein do not necessarily indicate that a “bottom” component is below a “top” component, or that a component that is “below” is indeed “below” another component or that a component that is “above” is indeed “above” another component. As such, directions, components or both may be flipped, rotated, moved in space, placed in a diagonal orientation or position, placed horizontally or vertically, or similarly modified. Accordingly, it will be appreciated that the terms “bottom”, “below”, “top” and “above” may be used herein for exemplary purposes only, to illustrate the relative positioning or placement of certain components, to indicate a first and a second component or to do both.

Any publications, including patents, patent applications and articles, referenced or mentioned in this specification are herein incorporated in their entirety into the specification, to the same extent as if each individual publication was specifically and individually indicated to be incorporated herein. In addition, citation or identification of any reference in the description of some embodiments of the invention shall not be construed as an admission that such reference is available as prior art to the present invention.

The purpose of preferred embodiments of the present invention is to create a solution that handles the problem of more detailed user-intended ink/toner saving. The solution provides a color image-pixels-data printing apparatus for processing image data so that the amount of ink/toner developer used for the reproduction of an image-pixel-data is reduced while controlling the intended level of quality of the original image. The disclosed colorants-saving apparatus is supported by methods that differentially treat different parts of image-pixels-data allocated via computer vision models. Also within the scope of the present invention are additional approaches for applying filtering algorithms, such as a printer driver (controller) which processes input image data to generate printable image data, for the purpose of achieving differential colorants saving and other purposes of the invention.

According to one aspect of the present invention, the printer driver, as described herein, includes an object identifying unit which identifies a type of an object included in the input image-pixels-data. The printer driver automatically sets the deferential image treatment for user-intended saving level.

The disclosed embodiments enable achieving discriminatory ink/toner saving for different image parts, i.e. image objects of different types, monotonic areas, segmenting borders, color bands and more. Namely, ink/toner saving at user-intended quality level printing can be achieved with respect to only a selected portion of the printed image while maintaining original image quality for other portions of the image that require high quality printing. The processes are implied within printer driver in hardware device or software for high processing speed.

The invention also enables the user to manually mark regions of interest in the image-pixels-data using Graphic User Interface (GUI) tools. In the regions of interest the process of ink/toner saving will not be applied, thus maintaining original image quality. In the ink/toner deferential saving operation CMYK colorants are controlled separately for CMY colors and for black (K). CMY-colorants values are reduced accordingly to the differential regions and according to the value of K-colorant, such that, the more K-colorant is used the more CMY-colorants reduction is applied. The K-colorant value is reduced accordingly to the differential regions. Using a dedicated color perception process based on bordering effect, also named color framing, the disclosed system enables maintaining visual intensity perception response to illumination.

An additional type of CMY-colorants saving is achieved by using CMY consumption balancing for printers that uses combined three-color container in a single cartridge. In this type of printers, whenever one of the colorant runs out, the integrated three-color cartridge becomes useless, although other colorants are still available in their containers. For addressing this problem, preferred embodiments of the invention use a continuously controlled tracking system to set C and Y and M colorants balanced consumption at lined-out level. The CMY-colorant values are balanced according to the differential regions and according to the value of K-colorant, so that the more K-colorant is used the more CMY-colorants balancing is applied. Thus, the CMY-colorants at their containers are reaching maximum parallel utilization ensuring that none of the CMY-colorants runs out before the others do.

According to additional embodiments of the present invention a different type of CMY-colorants saving is used at critical situation where at least one of the CMY-colorants is missing. The proposed solution enables partial color printing and the three-color cartridge is used to its maximal ink/toner colorants quantity. The proposed system enables users to manage all ink/toner saving methods and the ink/toner saving-quality levels may be controlled throughout.

The principle of the disclosed ink/toner saving and balancing of CMY color components invention is based on human perception and eye response to K-level dot coverage. According to embodiments of the present invention, whenever a printing device prints an image area where K-component is dominant, and is comprised of high ink/toner drop thickness demands, the printing device is commanded by the disclosed system and method to recalculate the relative consumptions of CMY-color components with respect to K component consumption. Larger amounts of K would more frequently cover CMY regions. In terms of light reflection, such overlapping regions are filtering the incoming light almost as if there is no CMY colors in these regions. The disclosed system and method therefore direct the printing system to evaluate the level of K-component in comparison to CMY-components and if the K-levels are high then it is instructed to save in CMY consumption leaving the K to be dominant, as it is originally perceived. Thus, it is built to further compress the size of printing documents digital file/stream, since areas of high K-component consumption are overriding the CMY-components. According to embodiments of the present invention, the mechanism may select adaptive proportional linear K-consumption with respect to the original component-level and compress the CMY color channel using varying quantization levels per pixel.

Additionally, the proposed system and method provide means for processing images in which the background comprises of artificial factors or relatively monotonic spectra and do not contribute much to the perceived image. The system and method employ advanced detection and region-separation of background versus foreground classification. This process enables controlling the separation of background and foreground regions so that higher ink/toner savings and balancing levels can be performed only in the background areas. The distinction between background and foreground regions in the image is performed using methods which are known to people who are skilled in the art.

In Addition, the disclosed solution also detects whether the input image is grayscale or color. The detected grayscale images are converted from CMY to CMYK color space using maximum grey component replacement (GCR). In maximum GCR the CMY components are zeroed, while the K is maximized. This allows maximum ink/toners saving. The ink/toner saving algorithm yields maximum effect when color-separation from CMY to CMYK color-space is done by using maximum GCR. On the other hand, this invention enables Ink/Toner savings and balancing even if non-GCR separation is used. Non-GCR separation is adequate for applications that requires minimum printed color fluctuations, while maximum GCR separation is adequate for applications that requires minimum printed luminosity fluctuations. The proposed ink/toner saving algorithm applies an adaptive separation procedure. The algorithm checks the boundaries of each image sample and applies a linear proportional separation process, varying from non-GCR to maximum GCR. In this way, the algorithm achieves better robustness for the printed device color fluctuations as well as for luminosity fluctuations.

A printing device may contain several hues of Cyan, several hues of Magenta, several hues of Yellow. The printing device takes the CMY color components and decomposes each of them to various hues. Therefore, saving ink/toner of the CMY colors, as performed by the proposed system and method, saves ink/toner for the various decomposed hues.

In addition to saving ink/toner of CMY colors, the disclosed solution also specifies a method for balancing the usage of CMY colors. As is known to people who are skilled in the art, during the printing procedure, when printing on an unprinted segment of the paper, the first drops of ink/toner poured onto the paper are absorbed into the paper and are not visible to the human eye. The proposed system and method make use of this fact to balance the usage of CMY colors. According to embodiments of the present invention the proposed system and method analyze the printed data and identify whether one or two of the CMY colors is disproportionably used when compared with the other color(s). In such cases the method includes the step of using small amounts of one of the colors which is absent from the printed data or disproportionably less in use on the printed area before using the appropriate color. These drops of the other color are absorbed into the paper and are not visible in the final print. Thus, smaller amounts of ink/toner of the appropriate CMY color need to be used in the given printed area and some use is made of the other color(s) resulting in a more balanced use of the different CMY colors.

Embodiments of the present invention enable continuing the printing procedure whenever at least one of the CMY colors is finished and is therefore not available while printing. Existing printing apparatuses and method usually respond to this situation in one of two ways. According to the first the printing procedure is brought to a halt all together; according to the second the printing procedure is continued and the absence of the colors is ignored. While the first way abstracts the printing procedure all together, the second leaves segments of the printed information blank. The proposed system and method offer a solution to this problem. Whenever at least one of the colors is identified as absent in the printing device, one of the other colors is used to replace it. Although this solution causes a distortion in the colors of the printed information, it nevertheless ensures that all information is printed. A detailed explanation of the methods of implementing this feature of the present invention is described below.

The following are principle definitions, user parameters and global parameters of the algorithms used in the detailed description, and the list of items of the invention brought herein.

### DEFINITIONS

ψ=0—the term refers to RGB color-space (R-red, G-green, B-blue). Intensity values are in the range of 0-255, where 0 value indicates no intensity and 255 value indicates maximum intensity.

ψ=1—the term refers to CMY color space (C-cyan, M-magenta, Y-yellow). Ink consumption values are given in percentages, where 0 value indicates no ink consumption and 100 value indicates maximum ink consumption.

ψ=2—the term refers to CMYK color space (C-cyan, M-magenta, Y-yellow, K-black). Ink consumption values are given in percentages, where 0 value indicates no ink consumption and 100 value indicates maximum ink consumption.

ψ=3—the term refers to Lab color space (L-represent lightness, a-approximate redness-greenness, b-approximate yellowness-blueness).

Spatial image (raster graphic)—an image is defined by A^{ψ}(x, y, z), B^{ψ}(x, y, z) functions of ψ images pixel space, x is the image horizontal axis coordinate, y is the image vertical axis coordinate and z image color channel. For example A^{ψ=2}(0, 0, 3) indicates the K-black ink consumption of the image in image origin coordinates. The image size is defined by it Nₓ width and height N_{y} and is measured in pixels units.

Mask image (raster graphic)—a mask image is defined by M(x, y) function, x is the image horizontal axis coordinate and y is the image vertical axis coordinate. The image mask is monochromatic and in the 0≦M(x, y)≦1 range. Higher pixel values reduce the ink/toner saving and color balancing.

Vector Graphic Color—the colors of vector graphic objects is defined by V^{ψ}(\grave{r},z), U^{ψ}(\vec{r},z) functions of ψ color space, \vec{r} vector space indicating the z-th color channel.

Vector and Bitmap Fonts Color—the colors of font objects are defined by F^{ψ}(i, z), G^{ψ}(i, z) functions of ψ color space, i=0 indicates the foreground color, i=1 indicates the background color, i=2 indicates the outline color and z indicates the color channel.

$${MAX}_{x , y} ( {M}_{1} ( x , y ) , {M}_{2} ( x , y ) , ⋯ , {M}_{n} ( x , y ) )$$

the function

$${MAX}_{x , y}$$

returns the maximum value among the (M₁(x, y), M₂(x, y), . . . , Mₙ(x, y)) image masks in every image coordinates <x, y>.

$${MIN}_{x , y} ( {M}_{1} ( x , y ) , {M}_{2} ( x , y ) , ⋯ , {M}_{n} ( x , y ) )$$

—the function

$${MIN}_{x , y}$$

returns the minimum value among the (M₁(x, y), M₂(x, y), . . . , Mₙ(x, y)) image masks in every image coordinates <x, y>.

$${MEAN}_{x , y} ( A ( x , y ) , w )$$

the function

$${MEAN}_{x , y}$$

return the arithmetic mean value in every A(x, y) image pixel coordinates <x, y> from a running window of w×w pixels size.
User Parameters

Sⱼᵢ^{K}—the term refers to K-Ink saving, parameter in the 0≦Sⱼᵢ^{K}≦1 range.

Sⱼᵢ^{CMY}—the term refers to CMY-Ink saving parameter in the 0≦Sⱼᵢ^{CMY}≦1 range. Higher values reduce ink/toner saving. j and i correspond to the following scenarios:

j=0—the saving apply to the raster graphic object type. j=1—the saving apply to the vector graphic object type. j=2—the saving apply to the “Font” object type. i=0—all CMY-Inks available for printings. i=1—only one single CMY-ink color is absent. i=2—a pair of the CMY-inks color combinations are absent. i=3 all CMY-inks are absent.

Bⱼ^{CMY}—the term refers to CMY-ink consumption balancing parameter in the 0≦Bⱼ^{CMY}≦1 range. Higher value reduces the balancing. j corresponds to the following scenarios:

j=0—the balancing apply to the raster graphic object type. j=1—the balancing apply to the vector graphic object type. j=2—the balancing apply to the “Font” object type

Global Parameters of the Algorithms

Each algorithm has its own local parameters, which are separate from those of other block algorithms. However, all algorithms use a particular global parameter name and they all share a single copy of that parameter. Any assignment to that parameter, in any algorithm, is available to all the other algorithms. The algorithm global parameters names are
Sᵢ0≦i≦2,
Sᵢ^{C}0≦i≦2,
Bᵢ^{C}0≦i≦2,Sᵢ^{j}0≦i≦20≦j≦3

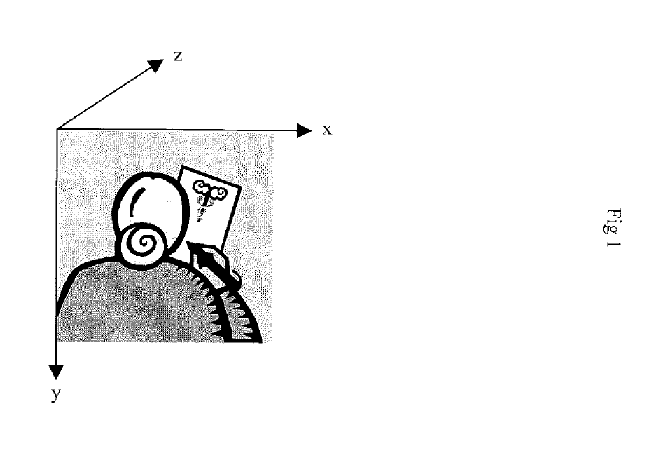

Some embodiments of the present invention provide an apparatus for ink/toner saving and balancing technology. FIG. 1 is a schematic illustration of typical figure mapped onto three dimensional space (3D): x, y and z, x and y denote the location of image-pixels-data in spatial two-dimensional distribution and z is the color channel given in ψ color space.

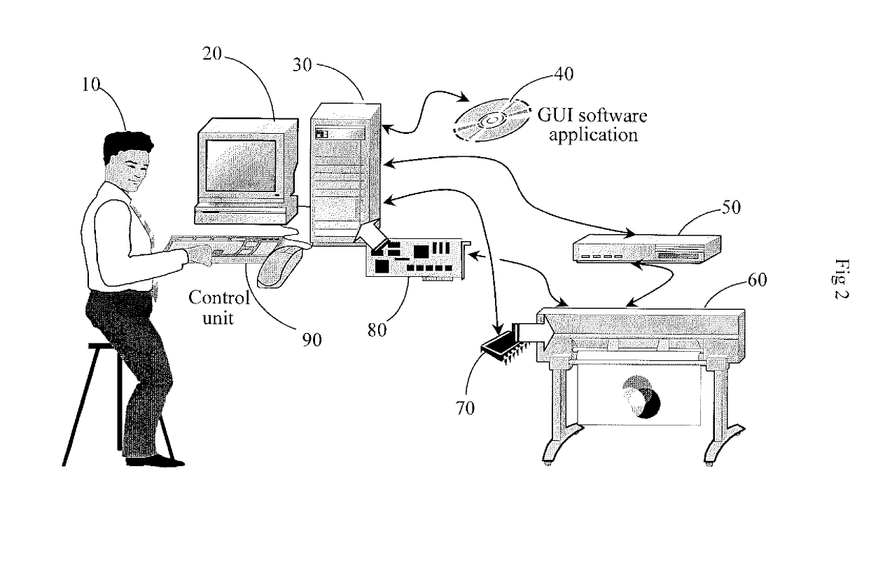

FIG. 2 is a schematic illustration of the principle flow diagram of the apparatus structure of ink/toner saving processes in hardware configuration. The apparatus comprises of six principle components: a Graphical User Monitor 20; a processing computer 30; GUI software application 40; hardware 50, 70 or 80 for ink/toner saving; a control unit 90; and an ink/toner printer device 60. User 10 may use any software application in the computer system that has an integrated printing option to generate hardcopy of image-pixels-data printouts. User 10 can observe the GUI software application 40 on an interactive Graphical User Monitor 20 by means of a control unit 90 in order to set the ink/toner saving amount and the printout quality feedback.

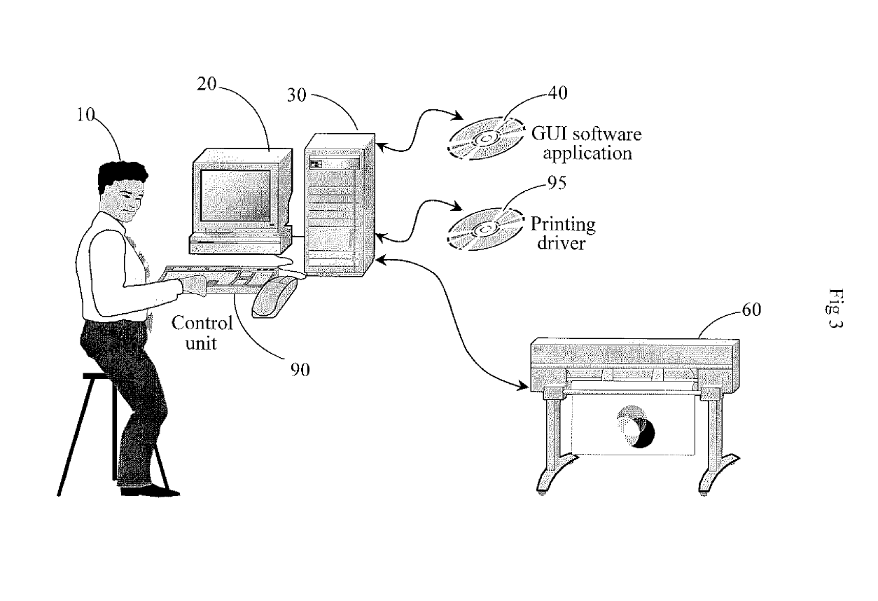

FIG. 3 is a schematic illustration of the principle flow diagram of the apparatus structure of ink/toner saving processes according to the software driver configurations of the present invention. According to the software driver configurations embodiments all ink/toner saving processes are performed by driver 95 installed on control unit 90 instead of by hardware components 50, 70 or 80 illustrated in FIG. 2. All other components of the ink/toner saving apparatus structure are the same as in FIG. 2a functioning in similar modes.

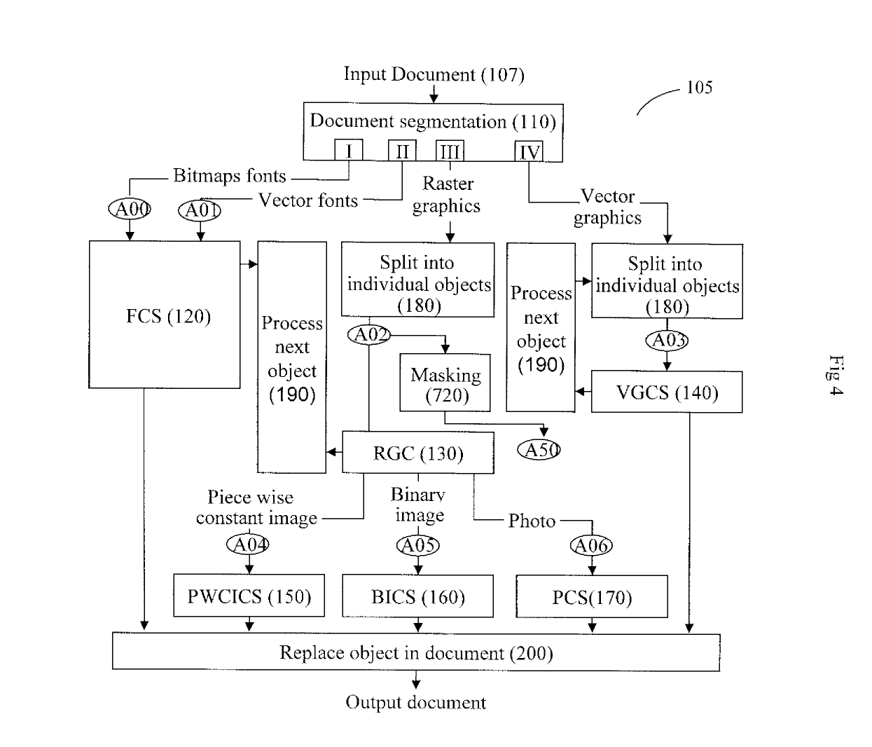

FIG. 4 is a schematic illustration of a block diagram of the principle techniques for ink/toner saving processes via CV masking and other methods. Block diagram 105 optionally applies to documents that may contain fonts, vector graphic objects, piecewise-constant images, binary images and photographs objects. The input for process 105 is the stream data of a document 107. The document data 107 is segmented 110 and the ink/toner saving process is performed on the segmented data. The input stream 107 is generated by any application having printout capability and transferred by the computer operating system 30 to the document segmentation 110 in the apparatus. The input data stream 107 that is segmented by unit 110 is outputted by the computer system 30. The format of the input data stream 107 is application and operating system and printer dependent. The stream format can include any partial combination of the following document object types, bitmaps fonts I, vector fonts II, raster graphics III and vector graphics IV.

The segmentation unit 110 decomposes the input document to various classes of object-types. Raster graphic objects are further split into individual object by Unit 180. Font objects are processed by Font Color Saving (FCS) unit 120, raster image objects are processed by the Raster Graphic Classification (RGC) unit 130 and vector image objects are processed by Vector Graphic Color Saving (VGCS) unit 140. The RGC 130 process classifies the raster image into three image-pixels-data types: piece wise constant images, binary images and photographs. Each of these image-pixels-data types are processed separately by the Piece Wise Constant Image Color Saving (PWCICS) 150, the Binary Image color Saving (BICS) 160, and the Photo Color Saving (PCS) 170, respectively. Unit 200 collects all objects before and after saving/balancing. Unit 200 automatically replaces all original objects by the processed ones. The system enables users to intervene in this process through its GUI and they may add or subtract objects from the list of processed objects.

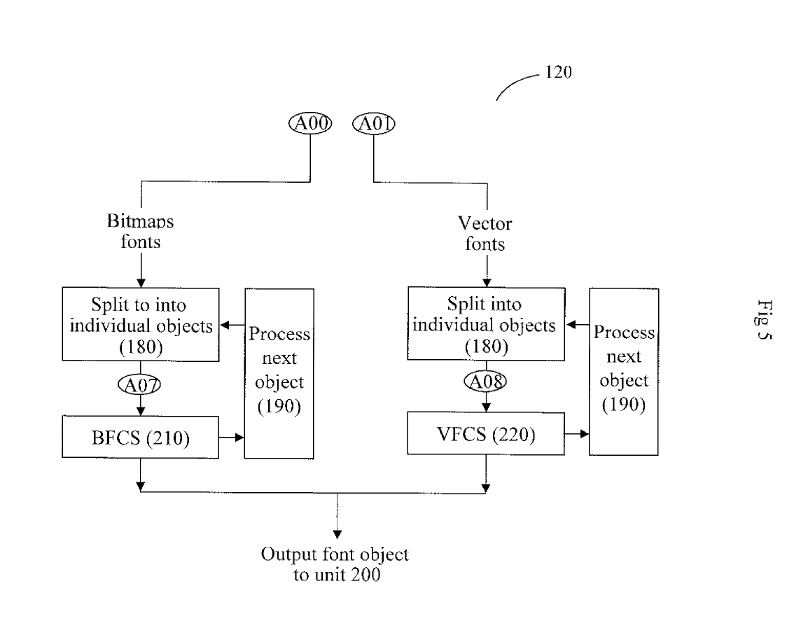

FIG. 5 is a schematic illustration of the block diagram of the principle techniques for saving ink/toner in font objects. Unit 180 is used to split the document text regions into individual font characters. The individual characters are then processed in saving and balancing subunits 210 and 220. Subunits 210 processes bitmap font objects and 220 processes vector font object. The output of subunits 210 and 220 are fed into unit 200.

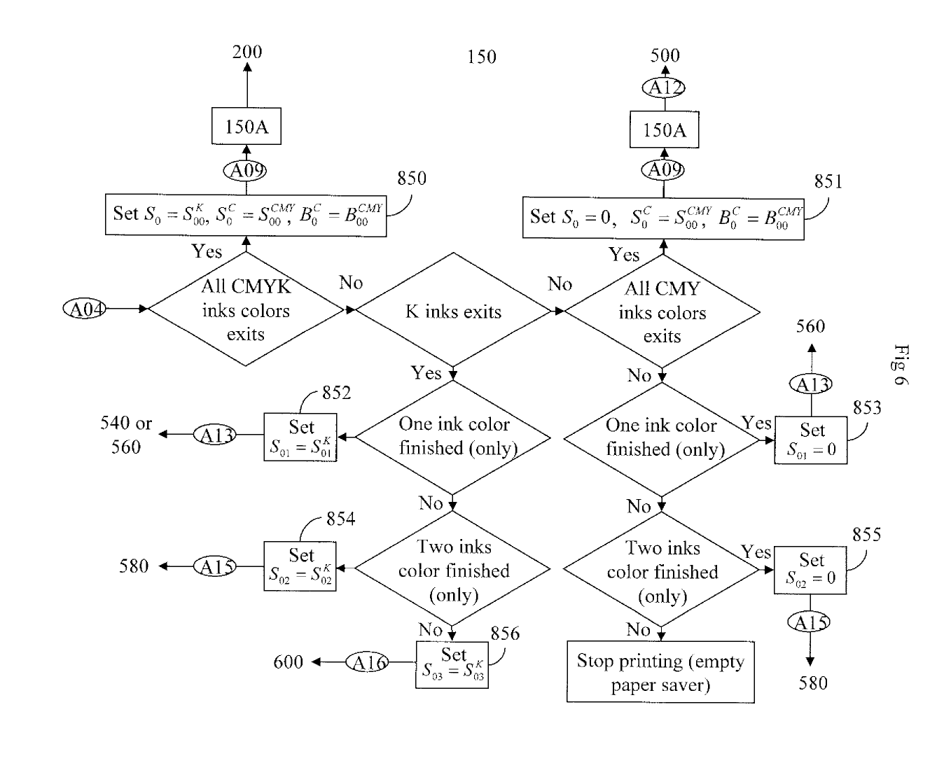

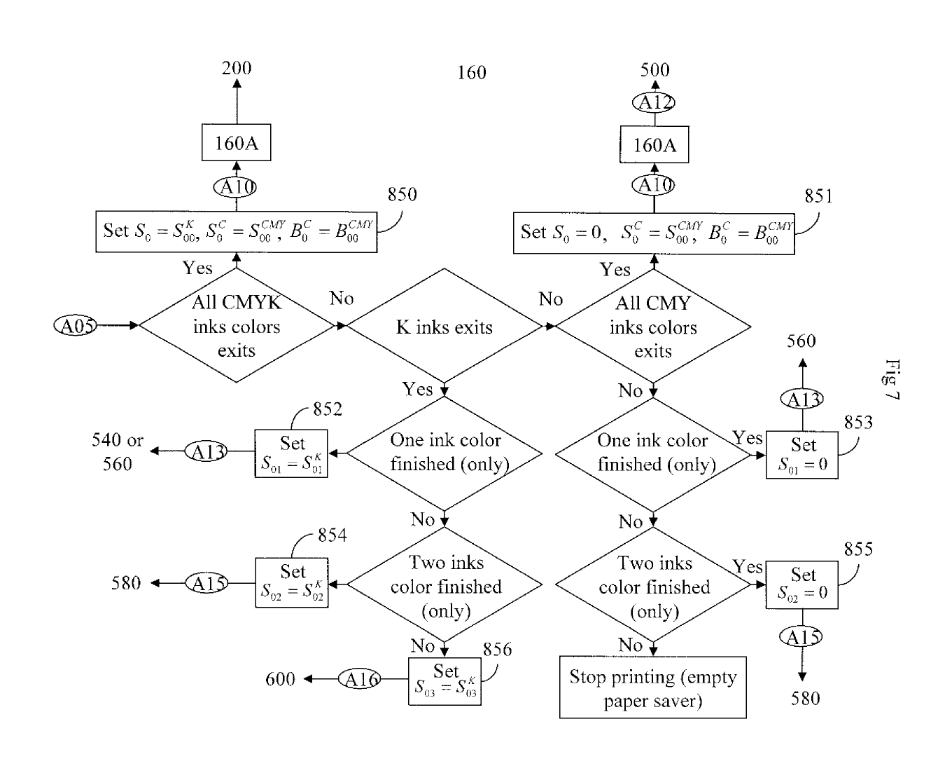

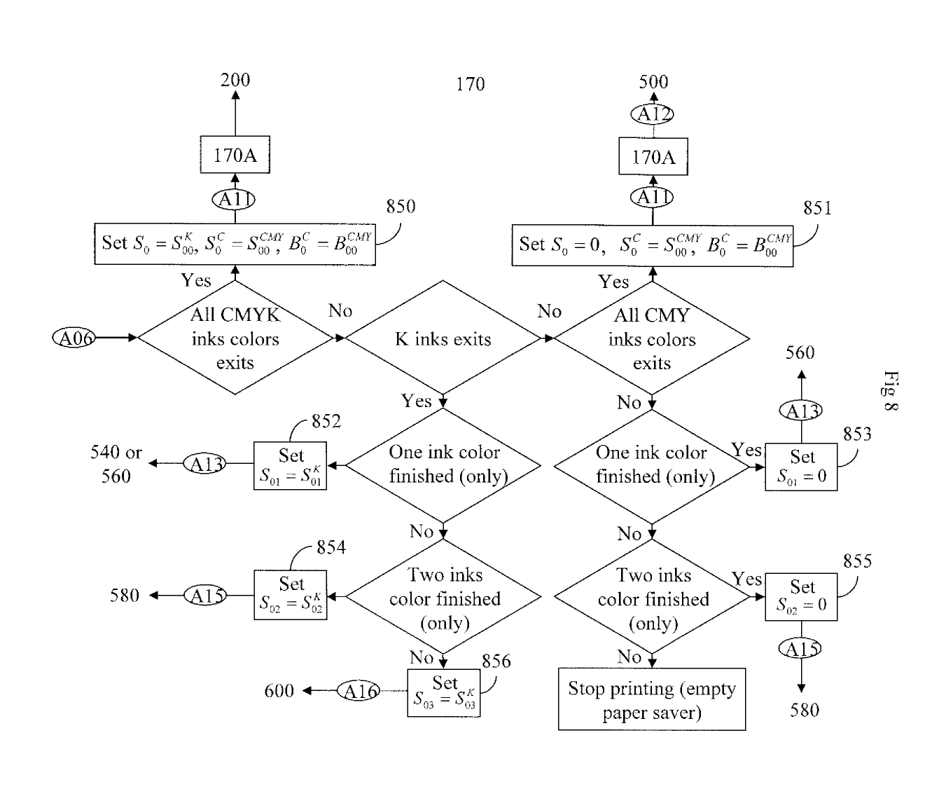

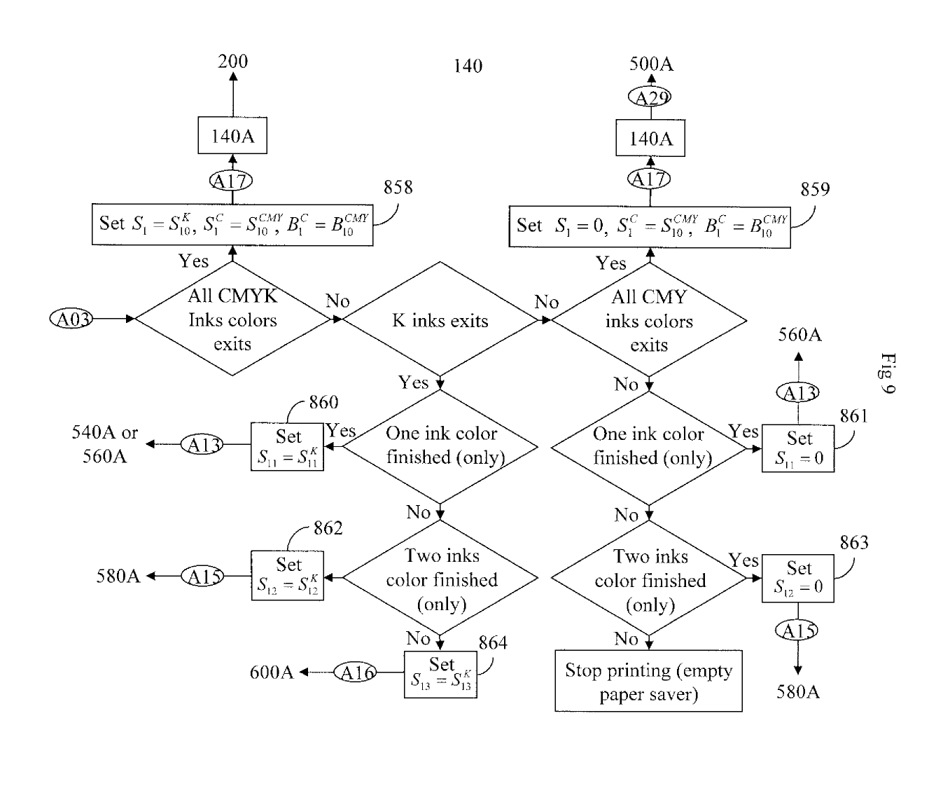

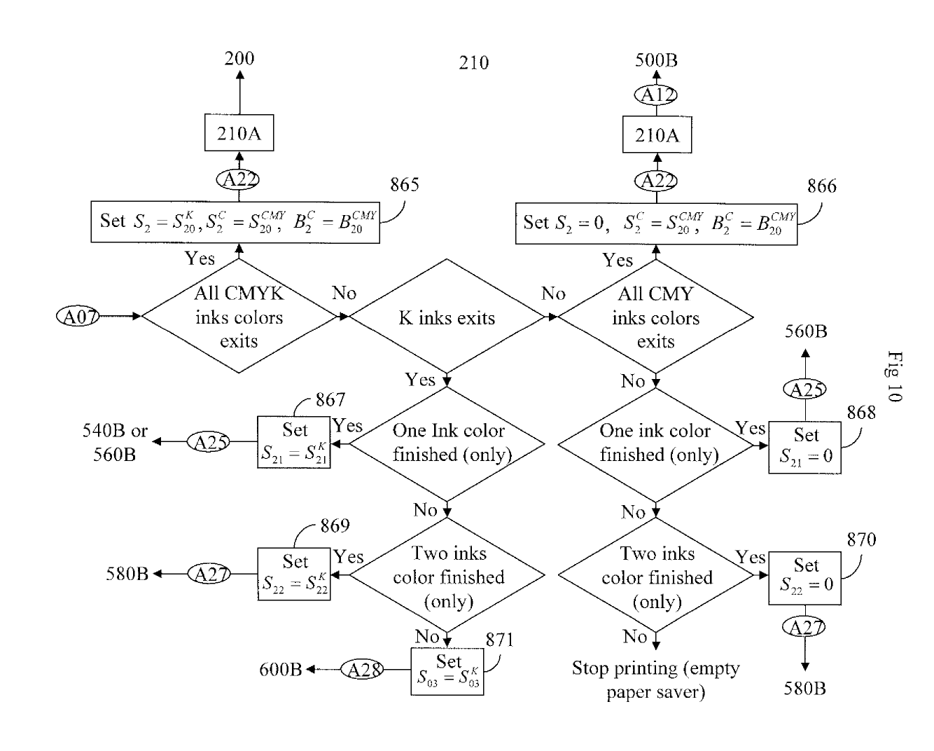

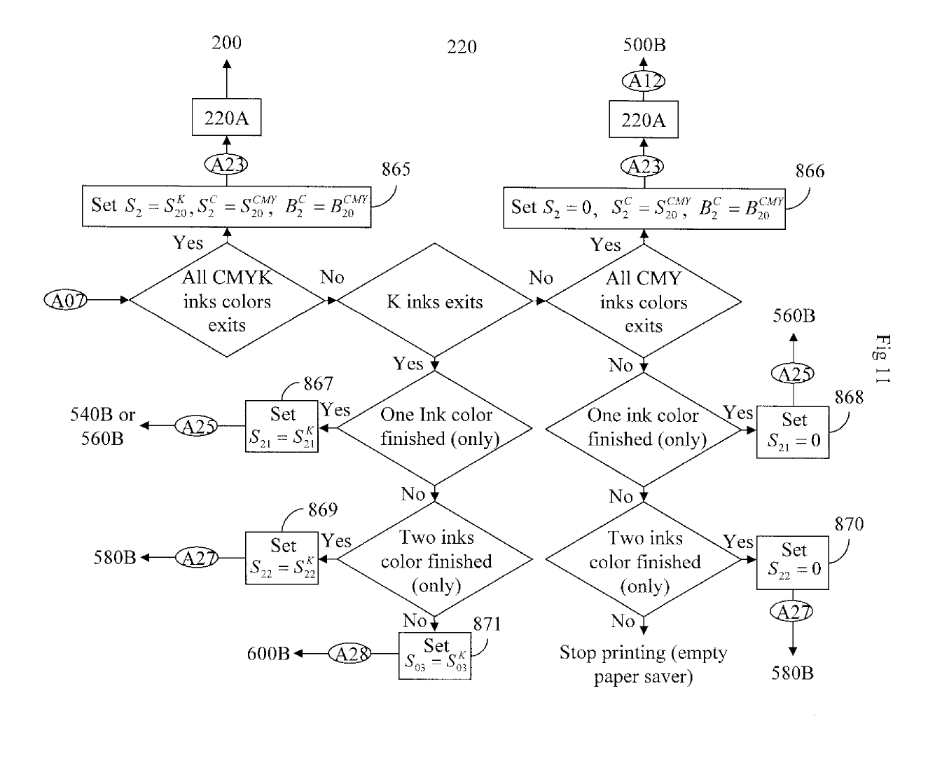

FIGS. 6 to 10 illustrate the algorithms for saving/balancing ink/toner usage whenever one of the ink/toner cartridges is missing. FIG. 6 relates to the piecewise constant image type of raster graphic. It includes block diagram number 150 and image entry point A04. FIG. 7 relates to the bitmap image of raster graphic. It includes block diagram number 160 and image entry point A05. FIG. 8 relates to the photo image of raster graphic. It includes block diagram number 170 and image entry point A06. FIG. 9 relates to vector graphic image. It includes block diagram number 140 with image entry point A03. FIG. 10 relates to the algorithm of processing bitmap fonts. It includes block diagram number 210 and font object entry point A07. FIG. 11 relates to the algorithm of processing vector font objects. It includes block diagram number 220 and font object entry point A08.

Reference is now made to FIG. 6. As a first step the algorithm checks whether all ink/toner color components are available for printing. Provided that all color components are available it executes unit 850:
Set S₀=S₀₀^{K},S₀^{C}=S₀₀^{CMY},B₀^{C}=B₀₀^{CMY}
and then unit 150A. If not all color components are available the algorithm checks all possible combinations of absent of CMYK ink/toner color components. If all CMY ink/toner color components exist and only K-ink/K-toner is absent, the algorithm executes unit 851:
Set S₀=0,S₀^{C}=S₀₀^{CMY},B₀^{C}=B₀₀^{CMY}
which is followed by unit 150A. If only one of CMY ink/toner color component is missing and K-ink/K-toner exists then the algorithm executes unit 852:
Set S₀₁=S₀₁^{K}
and then units 540 or 560; if K-ink/K-toner is also finished then the algorithm executes unit 853:
Set S₀₁=0
and then units 560. Provided that two of CMY ink/toner color components are absent and K-ink/K-toner exists then the algorithm executes unit 854:
Set S₀₂=S₀₂^{K}
and then unit 580; if K-ink/K-toner is also finished then the algorithm executes unit 855:
Set S₀₂=0

Set

and then unit 580. When all CMY ink/toner color components are absent but K-ink/K-toner exists then the algorithm executes unit 856:
Set S₀₃=S₀₃^{K}
which is followed by unit 600. If no ink/toner exists at all, then the algorithm stops printing.

Reference is now made to FIG. 7. As a first step the algorithm checks whether all ink/toner color components are available for printing. Provided that all color components are available it executes unit 850:
Set S₀=S₀₀^{K},S₀^{C}=S₀₀^{CMY},B₀^{C}=B₀₀^{CMY}
and then unit 160A. If not all color components are available the algorithm checks all possible combinations of absent of CMYK ink/toner color components. If all CMY ink/toner color components exist and only K-ink/K-toner is absent, the algorithm executes unit 851:
Set S₀=0,S₀^{C}=S₀₀^{CMY},B₀^{C}=B₀₀^{CMY}
which is followed by unit 160A. If only one of CMY ink/toner color component is missing and K-ink/K-toner exists then the algorithm executes unit 852:
Set S₀₁=S₀₁^{K}
and then units 540 or 560; if K-ink/K-toner is also finished then the algorithm executes unit 853:
Set S₀₁=0
and then units 560. Provided that two of CMY ink/toner color components are absent and K-ink/K-toner exists then the algorithm executes unit 854:
Set S₀₂=S₀₂^{K}
and then unit 580; if K-ink/K-toner is also finished then the algorithm executes unit 855:
Set S₀₂=0

Set

and then unit 580. When all CMY ink/toner color components are absent but K-ink/K-toner exists then the algorithm executes unit 856:
Set S₀₃=S₀₃^{K}
which is followed by unit 600. If no ink/toner exists at all, then the algorithm stops printing.

Reference is now made to FIG. 8. As a first step the algorithm checks whether all ink/toner color components are available for printing. Provided that all color components are available it executes unit 850:
Set S₀=S₀₀^{K},S₀^{C}=S₀₀^{CMY},B₀^{C}=B₀₀^{CMY}
and then unit 170A. If not all color components are available the algorithm checks all possible combinations of absent of CMYK ink/toner color components. If all CMY ink/toner color components exist and only K-ink/K-toner is absent, the algorithm executes unit 851
Set S₀=0,S₀^{C}=S₀₀^{CMY},B₀^{C}=B₀₀^{CMY}
which is followed by unit 170A. If only one of CMY ink/toner color component is missing and K-ink/K-toner exists then the algorithm executes unit 852:
Set S₀₁=S₀₁^{K}
and then units 540 or 560; if K-ink/K-toner is also finished then the algorithm executes unit 853:
Set S₀₁=0
and then units 560. Provided that two of CMY ink/toner color components are absent and K-ink/K-toner exists then the algorithm executes unit 854:
Set S₀₂=S₀₂^{K}
and then unit 580; if K-ink/K-toner is also finished then the algorithm executes unit 855:
Set S₀₂=0
and then unit 580. When all CMY ink/toner color components are absent but K-ink/K-toner exists then the algorithm executes unit 856:
Set S₀₃=S₀₃^{K}
which is followed by unit 600. If no ink/toner exists at all, then the algorithm stops printing.

Reference is now made to FIG. 9. As a first step the algorithm checks whether all ink/toner color components are available for printing. Provided that all color components are available it executes unit 858:
Set S₁=S₁₀^{K},S₁^{C}=S₁₀^{CMY},B₁^{C}=B₁₀^{CMY}
and then unit 140A. If not all color components are available the algorithm checks all possible combinations of absent of CMYK ink/toner color components. If all CMY ink/toner color components exist and only K-ink/K-toner is absent, the algorithm executes unit 859:
Set S₁=0,S₁^{C}=S₁₀^{CMY},B₁^{C}=B₁₀^{CMY}
which is followed by unit 140A. If only one of CMY ink/toner color component is missing and K-ink/K-toner exists then the algorithm executes unit 860:
Set S₁₁=S₁₁^{K}

Set

and then units 540A or 560A; if K-ink/K-toner is also finished then the algorithm executes unit 861:
Set S₁₁=0
and then units 560A. Provided that two of CMY ink/toner color components are absent and K-ink/K-toner exists then the algorithm executes unit 862:
Set S₁₂=S₁₂^{K}
and then unit 580A; if K-ink/K-toner is also finished then the algorithm executes unit 863:
Set S₁₂=0
and then unit 580A. When all CMY ink/toner color components are absent but K-ink/K-toner exists then the algorithm executes unit 864:
Set S₁₃=S₁₃^{K}
which is followed by unit 600A. If no ink/toner exists at all, then the algorithm stops printing.

Reference is now made to FIG. 10. As a first step the algorithm checks whether all ink/toner color components are available for printing. Provided that all color components are available it executes unit 865:
Set S₂=S₂₀^{K},S₂^{C}=S₂₀^{CMY},B₂^{C}=B₂₀^{CMY}
and then unit 210A. If not all color components are available the algorithm checks all possible combinations of absent of CMYK ink/toner color components. If all CMY ink/toner color components exist and only K-ink/K-toner is absent, the algorithm executes unit 866:
Set S₂=0,S₂^{C}=S₂₀^{CMY},B₂^{C}=B₂₀^{CMY}
which is followed by unit 210A. If only one of CMY ink/toner color component is missing and K-ink/K-toner exists then the algorithm executes unit 867:
Set S₂₁=S₂₁^{K}
and then units 540B or 560B; if K-ink/K-toner is also finished then the algorithm executes unit 868:
Set S₂₁=0
and then units 560B. Provided that two of CMY ink/toner color components arc absent and K-ink/K-toner exists then the algorithm executes unit 869:
Set S₂₂=S₂₂^{K}
and then unit 580B; if K-ink/K-toner is also finished then the algorithm executes unit 870:
Set S₂₂=0
and then unit 580B. When all CMY ink/toner color components are absent but K-ink/K-toner exists then the algorithm executes unit 871:
Set S₀₃=S₀₃^{K}
which is followed by unit 600B. If no ink/toner exists at all, then the algorithm stops printing.

Reference is now made to FIG. 11. As a first step the algorithm checks whether all ink/toner color components are available for printing. Provided that all color components are available it executes unit 865:

Set

and then unit 220A. If not all color components are available the algorithm checks all possible combinations of absent of CMYK ink/toner color components. If all CMY ink/toner color components exist and only K-ink/K-toner is absent, the algorithm executes unit 866:
Set S₂=0,S₂^{C}=S₂₀^{CMY},B₂^{C}=B₂₀^{CMY}
which is followed by unit 220A. If only one of CMY ink/toner color component is missing and K-ink/K-toner exists then the algorithm executes unit 867:
Set S₂₁=S₂₁^{K}
and then units 540B or 560B; if K-ink/K-toner is also finished then the algorithm executes unit 868:
Set S₂₁=0
and then units 560B. Provided that two of CMY ink/toner color components are absent and K-ink/K-toner exists then the algorithm executes unit 869:
Set S₂₂=S₂₂^{K}
and then unit 580B; if K-ink/K-toner is also finished then the algorithm executes unit 870:
Set S₂₂=0
and then unit 580B, When all CMY ink/toner color components are absent but K-ink/K-toner exists then the algorithm executes unit 871:
Set S₀₃=S₀₃^{K}
which is followed by unit 600B. If no ink/toner exists at all, then the algorithm stops printing.

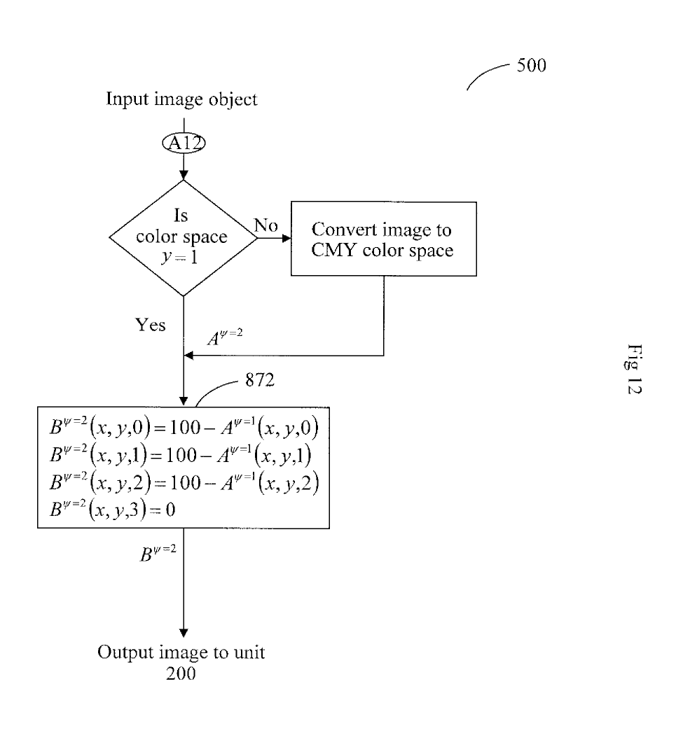

FIGS. 12, 13 and 14 illustrate the algorithms which are performed when printing with empty K-ink/K-toner cartridges. FIG. 12 illustrates flowchart of unit 500 for processing raster graphic. In this algorithm the process checks first if the input objects color space is CMY, and if false (no) then it converts the color space to CMY. Then the process executes unit number 872, which includes the following formulas:
B^{ψ=2}(x,y,0)=100−A^{ψ=1}(x,y,0)
B^{ψ=2}(x,y,1)=100−A^{ψ=1}(x,y,1)
B^{ψ=2}(x,y,2)=100−A^{ψ=1}(x,y,2)
B^{ψ=2}(x,y,3)=0

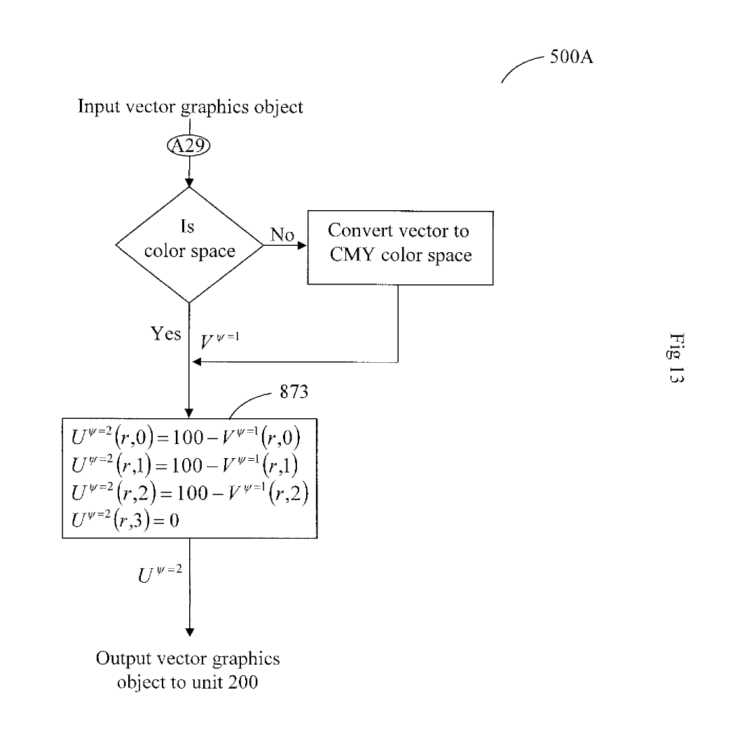

FIG. 13 illustrates flowchart of unit 500A for processing vector graphic. In this algorithm the process checks first if the input objects color space is CMY, and if false (no) then it converts the color space to CMY. Then the process executes unit number 873, which includes the following formulas:
U^{ψ=2}(r,0)=100−V^{ψ=1}(r,0)
U^{ψ=2}(r,1)=100−V^{ψ=1}(r,1)
U^{ψ=2}(r,2)=100−V^{ψ=1}(r,2)
U^{ψ=2}(r,3)=0

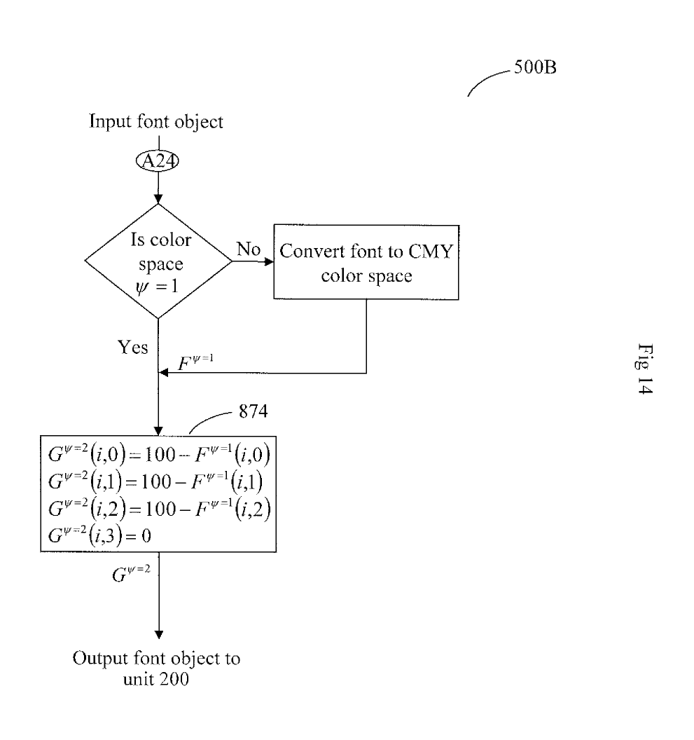

FIG. 14 illustrates flowchart of unit 500B for processing font objects. In this algorithm the process checks first if the input objects color space is CMY, and if false (no) then it converts the color space to CMY. Then the process executes unit number 874, which includes the following formulas:
G^{ψ=2}(i,0)=100−F^{ψ=1}(i,0)
G^{ψ=2}(i,1)=100−F^{ψ=1}(i,1)
G^{ψ=2}(i,2)=100−F^{ψ=1}(i,2)
G^{ψ=2}(i,3)=0

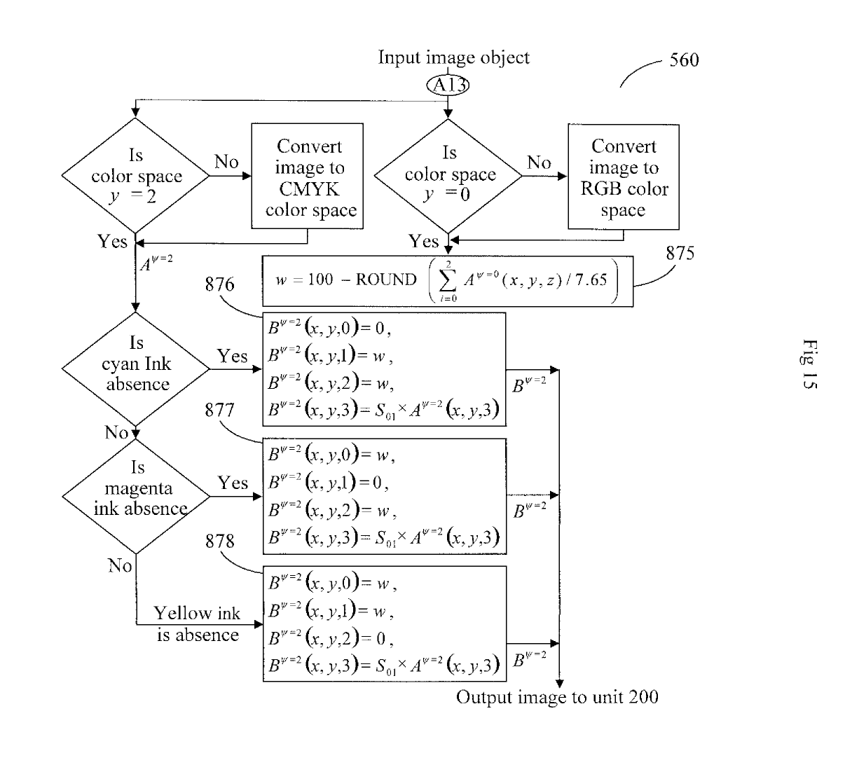

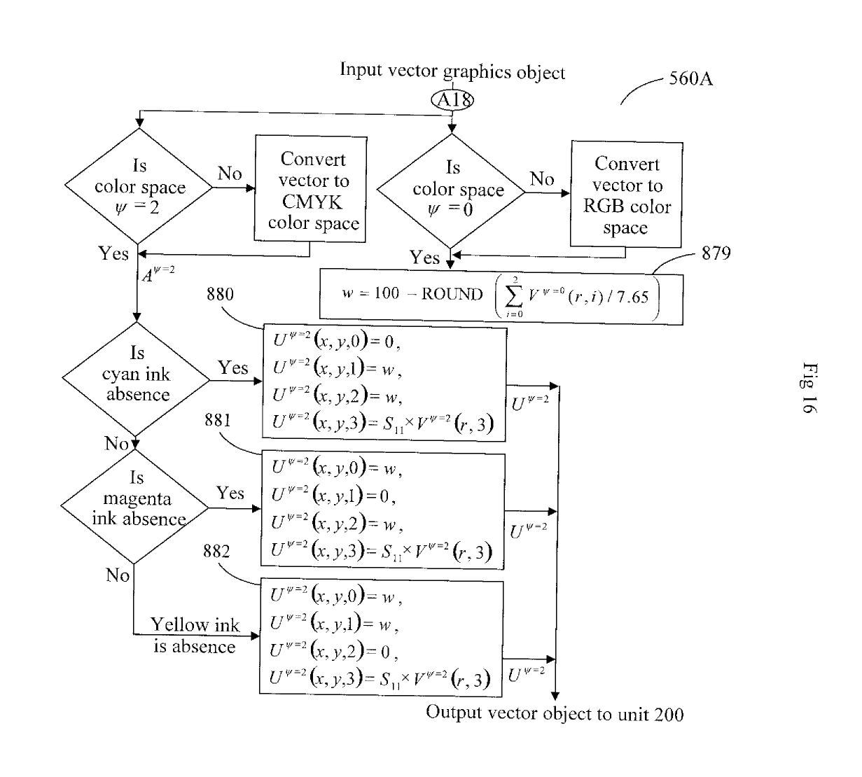

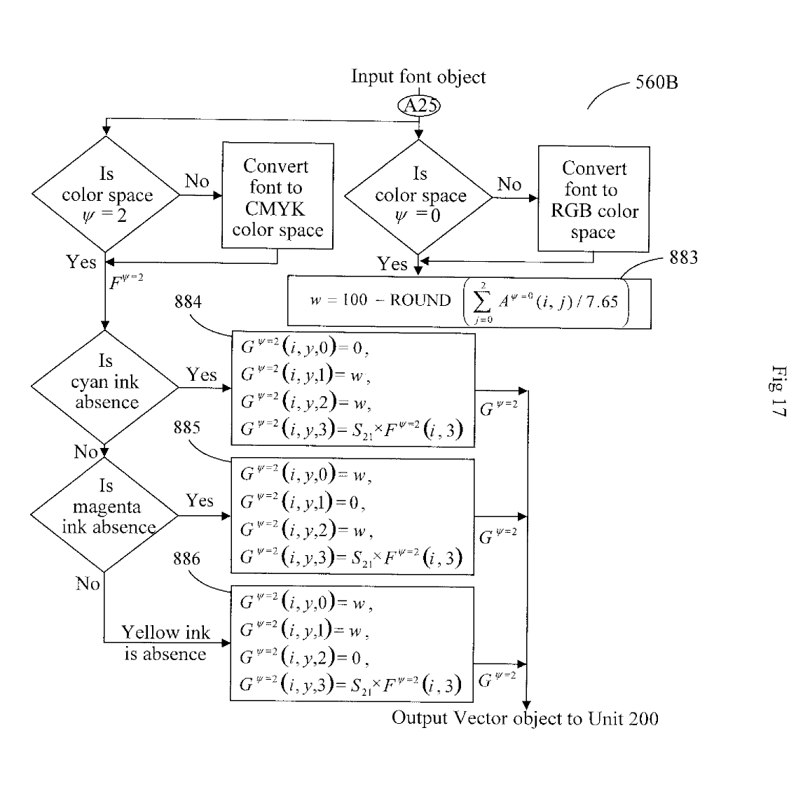

FIGS. 15, 16 and 17 illustrate the algorithms which enable ink/toner saving and printing whenever only one of the CMY ink/toner components is absent. FIG. 15 illustrates algorithm of unit 560 for processing raster graphic; FIG. 16 illustrates algorithm of unit 560A for processing vector graphic; and FIG. 17 illustrates algorithm of unit 560B for processing font objects. In these algorithms the process checks first if the input objects color space is RGB, and if false (no) then it converts the color space to RGB. Referring to FIG. 15 the algorithm includes the step of calculating w by executing unit number 875:

$$w = 100 - ROUND ( {\sum }_{i = 0}^{2} {A}^{ψ = 0} ( x , y , z ) / 7.65 )$$

Next, the process checks if the input objects color space is CMYK, and if false (no) then it converts the color space to CMYK. Then the process checks which of the CMY color component is missing and applies the computed w. In the case of cyan-absence the process executes unit number 876:
B^{ψ=2}(x,y,0)=0,
B^{ψ=2}(x,y,1)=w,
B^{ψ=2}(x,y,2)=w,
B^{ψ=2}(x,y,3)=S₀₁×A^{ψ=2}(x,y,3)

In the case of magenta-absence the process executes unit number 877;
B^{ψ=2}(x,y,0)=w,
B^{ψ=2}(x,y,1)=0,
B^{ψ=2}(x,y,2)=w,
B^{ψ=2}(x,y,3)=S₀₁×A^{ψ=2}(x,y,3)

In the case of yellow-absence the process executes unit number 878:
B^{ψ=2}(x,y0)=w,
B^{ψ=2}(x,y,1)=w,
B^{ψ=2}(x,y,2)=0,
B^{ψ=2}(x,y,3)=S₀×A^{ψ=2}(x,y,3)

Referring to FIG. 16 the algorithm includes the step of calculating w by executing unit number 879:

$$w = 100 - ROUND ( {\sum }_{i = 0}^{2} {V}^{ψ = 0} ( r , i ) / 7.65 )$$

Next, the process checks if the input objects color space is CMYK, and if false (no) then it converts the color space to CMYK. Then the process checks which of the CMY color component is missing and applies the computed w. In the case of cyan-absence the process executes unit number 880:
U^{ψ=2}(x,y,0)=0,
U^{ψ=2}(x,y,1)=w,
U^{ψ=2}(x,y,2)=w,
U^{ψ=2}(x,y,3)=S₁₁×V^{ψ=2}(r,3)

In the case of magenta-absence the process executes unit number 881:
U^{ψ=2}(x,y,0)=w,
U^{ψ=2}(x,y,1)=0,
U^{ψ=2}(x,y,2)=w,
U^{ψ=2}(x,y,3)=S₁₁×V^{ψ=2}(r,3)

In the case of yellow-absence the process executes unit number 882:
U^{ψ=2}(x,y,0)=w,
U^{ψ=2}(x,y,1)=w,
U^{ψ=2}(x,y,2)=0,
U^{ψ=2}(x,y,3)=S₁₁×V^{ψ=2}(r,3)

Referring to FIG. 17 the algorithm includes the step of calculating w by executing unit number 883;

$$w = 100 - ROUND ( {\sum }_{j = 0}^{2} {A}^{ψ = 0} ( i , j ) / 7.65 )$$

Next, the process checks if the input objects color space is CMYK, and if false (no) then it converts the color space to CMYK. Then the process checks which of the CMY color component is missing and applies the computed w. In the case of cyan-absence the process executes unit number 884:
G^{ψ=2}(i,y,0)=0,
G^{ψ=2}(i,y,1)=w,
G^{ψ=2}(i,y,2)=w,
G^{ψ=2}(i,y,3)=S₂₁×F^{ψ=2}(i,3)

In the case of magenta-absence the process executes unit number 885:
G^{ψ=2}(i,y,0)=w,
G^{ψ=2}(i,y,1)=0,
G^{ψ=2}(i,y,2)=w,
G^{ψ=2}(i,y,3)=S₂₁×F^{ψ=2}(i,3)

In the case of yellow-absence the process executes unit number 886:
G^{ψ=2}(i,y,0)=w,
G^{ψ=2}(i,y,1)=w,
G^{ψ=2}(i,y,2)=0,
G^{ψ=2}(i,y,3)=S₂₁×F^{ψ=2}(i,3)

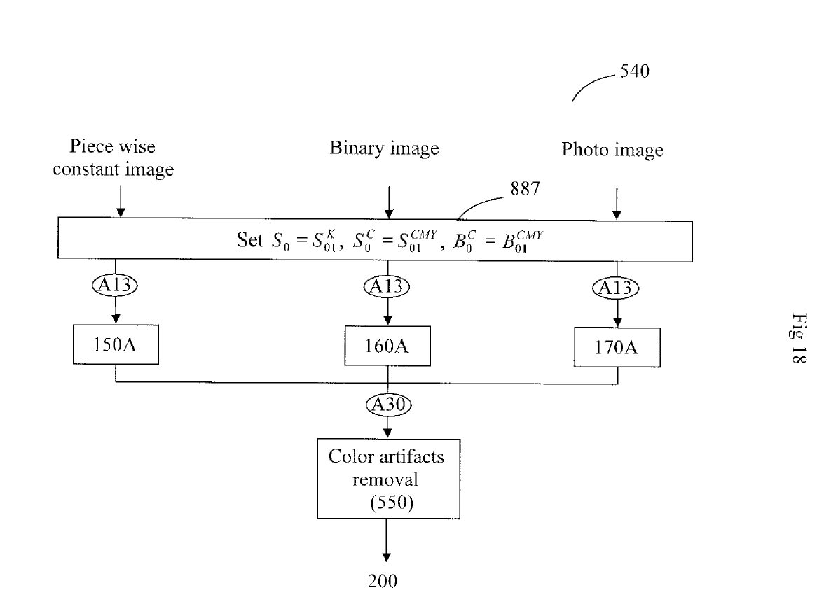

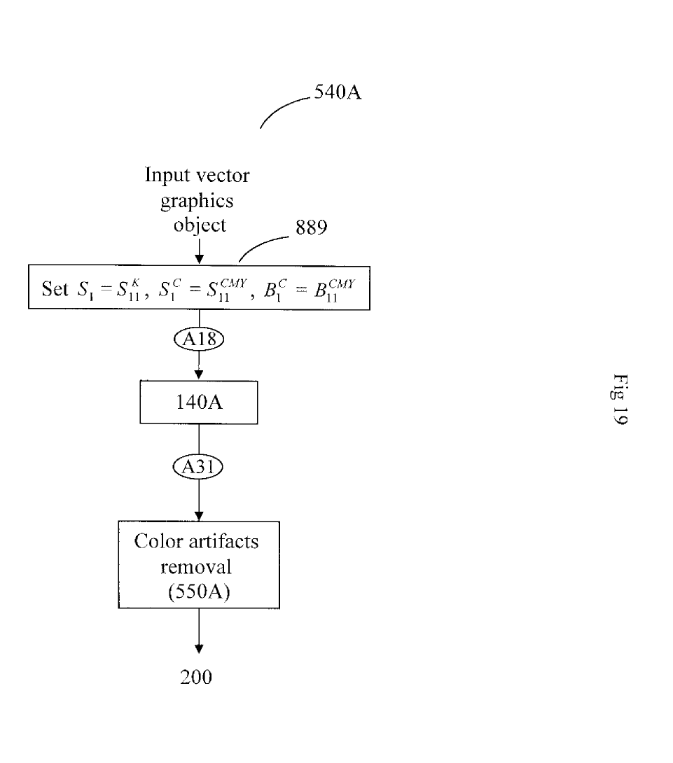

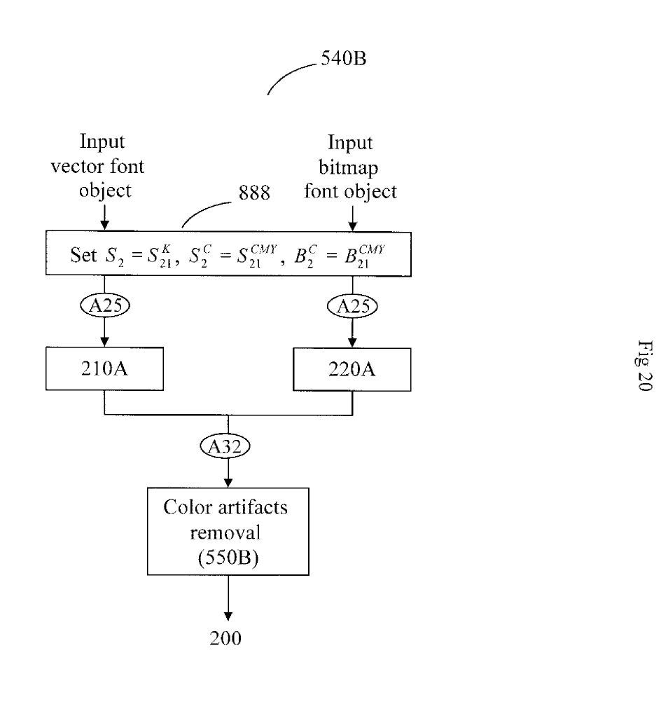

FIGS. 18, 19 and 20 illustrate the algorithms for carrying out ink/toner saving and balancing, whenever only one of the ink/toner CMY-components is absent. FIG. 18 illustrates algorithm unit 540 for processing raster graphic; FIG. 19 illustrates algorithm unit 540A for processing vector graphic; and FIG. 20 illustrates algorithm unit 540B for processing font objects, In the descendent-block diagram number 540 in FIG. 18 the process executes unit 887:
Set S₀=S₀₁^{K},S₀^{C}=S₀₁^{CMY},B₀^{C}=B₀₁^{CMY}
then executes unit 150A when processing piece wise constant image, executes unit 160A when processing binary image, or executes unit 170A when processing photo image. Next, the process executes unit 550 of color artifacts removal, In the descendent-block diagram number 540 in FIG. 19 the process executes unit 889:
Set S₁=S₁₁^{K},S₁^{C}=S₁^{CMY},B₁^{C}=B₁₁^{CMY}
then executes unit 140A when processing piece wise constant image. Next, the process executes unit 550A of color artifacts removal. In the descendent-block diagram number 540B in FIG. 20 the process executes unit 888:
Set S₂=S₂₁^{K},S₂^{C}=S₂₁^{CMY},B₂^{C}=B₂^{CMY}
then executes unit 210A when processing vector font objects or 220A when processing bitmap font objects. Next, the process executes unit 550B of color artifacts removal.

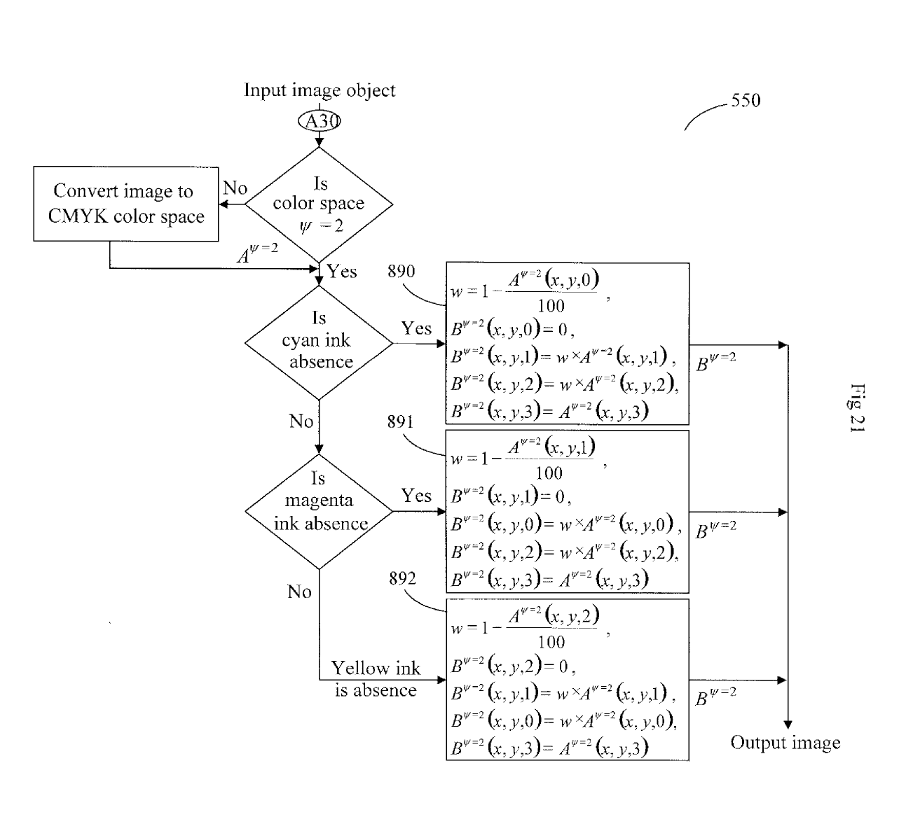

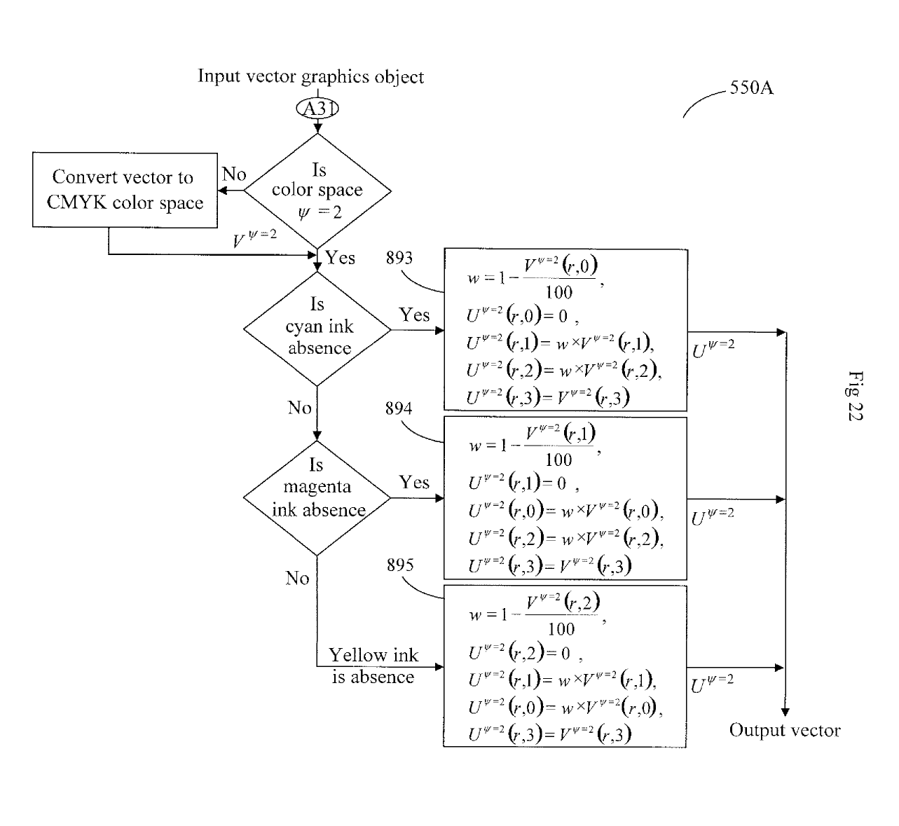

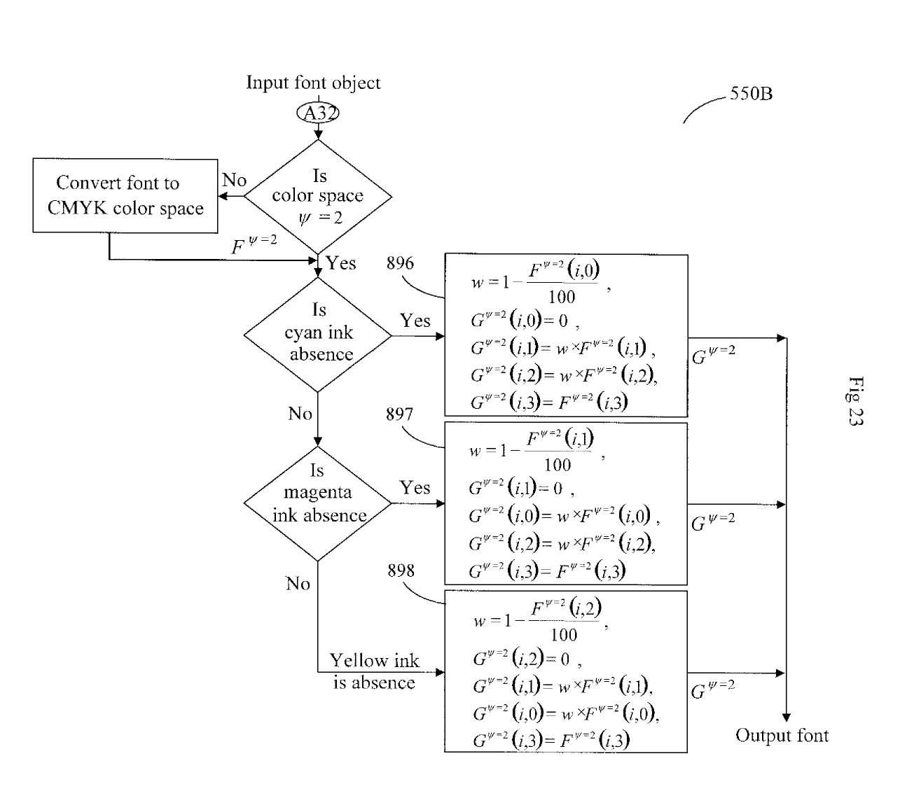

FIGS. 21, 22 and 23 illustrate algorithms which enable printing and removing color artifacts when only one of the ink/toner CMY-components is absent. FIG. 21 illustrates unit 550 for processing raster graphic; FIG. 22 illustrates unit 550A for processing vector graphic; and FIG. 23 illustrates unit 550B for processing font objects. In these algorithms the process checks first if the input objects color space is CMYK, and if false (no) then it converts the color space to CMYK. Then the process checks which of the CMY color component is missing, In FIG. 21 when cyan is absent the process executes unit 890:

$$w = 1 - \frac{{A}^{ψ = 2} ( x , y , 0 )}{100} , \\ {B}^{ψ = 2} ( x , y , 0 ) = 0 , \\ {B}^{ψ = 2} ( x , y , 1 ) = w \times {A}^{ψ = 2} ( x , y , 1 ) , \\ {B}^{ψ = 2} ( x , y , 2 ) = w \times {A}^{ψ = 2} ( x , y , 2 ) , \\ {B}^{ψ = 2} ( x , y , 3 ) = {A}^{ψ = 2} ( x , y , 3 )$$

When magenta is absent the process executes Unit 891:

$$w = 1 - \frac{{A}^{ψ = 2} ( x , y , 1 )}{100} , \\ {B}^{ψ = 2} ( x , y , 1 ) = 0 , \\ {B}^{ψ = 2} ( x , y , 0 ) = w \times {A}^{ψ = 2} ( x , y , 0 ) , \\ {B}^{ψ = 2} ( x , y , 2 ) = w \times {A}^{ψ = 2} ( x , y , 2 ) , \\ {B}^{ψ = 2} ( x , y , 3 ) = {A}^{ψ = 2} ( x , y , 3 )$$

When yellow is absent the process executes unit 892:

$$w = 1 - \frac{{A}^{ψ = 2} ( x , y , 2 )}{100} , \\ {B}^{ψ = 2} ( x , y , 2 ) = 0 , \\ {B}^{ψ = 2} ( x , y , 1 ) = w \times {A}^{ψ = 2} ( x , y , 1 ) , \\ {B}^{ψ = 2} ( x , y , 0 ) = w \times {A}^{ψ = 2} ( x , y , 0 ) , \\ {B}^{ψ = 2} ( x , y , 3 ) = {A}^{ψ = 2} ( x , y , 3 )$$

In FIG. 22 when cyan is absent the process executes unit 893:

$$w = 1 - \frac{{V}^{ψ = 2} ( r , 0 )}{100} , \\ {U}^{ψ = 2} ( r , 0 ) = 0 , \\ {U}^{ψ = 2} ( r , 1 ) = w \times {V}^{ψ = 2} ( r , 1 ) , \\ {U}^{ψ = 2} ( r , 2 ) = w \times {V}^{ψ = 2} ( r , 2 ) , \\ {U}^{ψ = 2} ( r , 3 ) = {V}^{ψ = 2} ( r , 3 )$$

When magenta is absent the process executes unit 894:

$$w = 1 - \frac{{V}^{ψ = 2} ( r , 1 )}{100} , \\ {U}^{ψ = 2} ( r , 1 ) = 0 , \\ {U}^{ψ = 2} ( r , 0 ) = w \times {V}^{ψ = 2} ( r , 0 ) , \\ {U}^{ψ = 2} ( r , 2 ) = w \times {V}^{ψ = 2} ( r , 2 ) , \\ {U}^{ψ = 2} ( r , 3 ) = {V}^{ψ = 2} ( r , 3 )$$

When yellow is absent the process executes unit 895:

$$w = 1 - \frac{{V}^{ψ = 2} ( r , 2 )}{100} , \\ {U}^{ψ = 2} ( r , 2 ) = 0 , \\ {U}^{ψ = 2} ( r , 1 ) = w \times {V}^{ψ = 2} ( r , 1 ) , \\ {U}^{ψ = 2} ( r , 0 ) = w \times {V}^{ψ = 2} ( r , 0 ) , \\ {U}^{ψ = 2} ( r , 3 ) = {V}^{ψ = 2} ( r , 3 )$$

In FIG. 23 when cyan is absent the process executes unit 896:

$$w = 1 - \frac{{F}^{ψ = 2} ( i , 0 )}{100} , \\ {G}^{ψ = 2} ( i , 0 ) = 0 , \\ {G}^{ψ = 2} ( i , 1 ) = w \times {F}^{ψ = 2} ( i , 1 ) , \\ {G}^{ψ = 2} ( i , 2 ) = w \times {F}^{ψ = 2} ( i , 2 ) , \\ {G}^{ψ = 2} ( i , 3 ) = {F}^{ψ = 2} ( i , 3 )$$

When magenta is absent the process executes unit 897.

$$w = 1 - \frac{{F}^{ψ = 2} ( i , 1 )}{100} , \\ {G}^{ψ = 2} ( i , 1 ) = 0 , \\ {G}^{ψ = 2} ( i , 0 ) = w \times {F}^{ψ = 2} ( i , 0 ) , \\ {G}^{ψ = 2} ( i , 2 ) = w \times {F}^{ψ = 2} ( i , 2 ) , \\ {G}^{ψ = 2} ( i , 3 ) = {F}^{ψ = 2} ( i , 3 )$$

When yellow is absent the process executes unit 898:

$$w = 1 - \frac{{F}^{ψ = 2} ( i , 2 )}{100} , \\ {G}^{ψ = 2} ( i , 2 ) = 0 , \\ {G}^{ψ = 2} ( i , 1 ) = w \times {F}^{ψ = 2} ( i , 1 ) , \\ {G}^{ψ = 2} ( i , 0 ) = w \times {F}^{ψ = 2} ( i , 0 ) , \\ {G}^{ψ = 2} ( i , 3 ) = {F}^{ψ = 2} ( i , 3 )$$

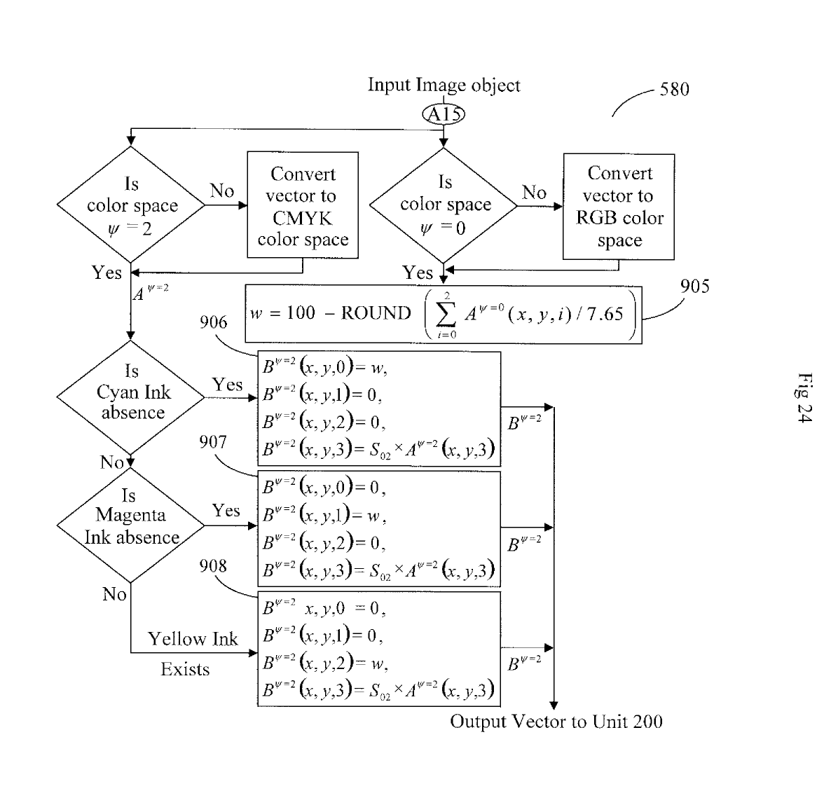

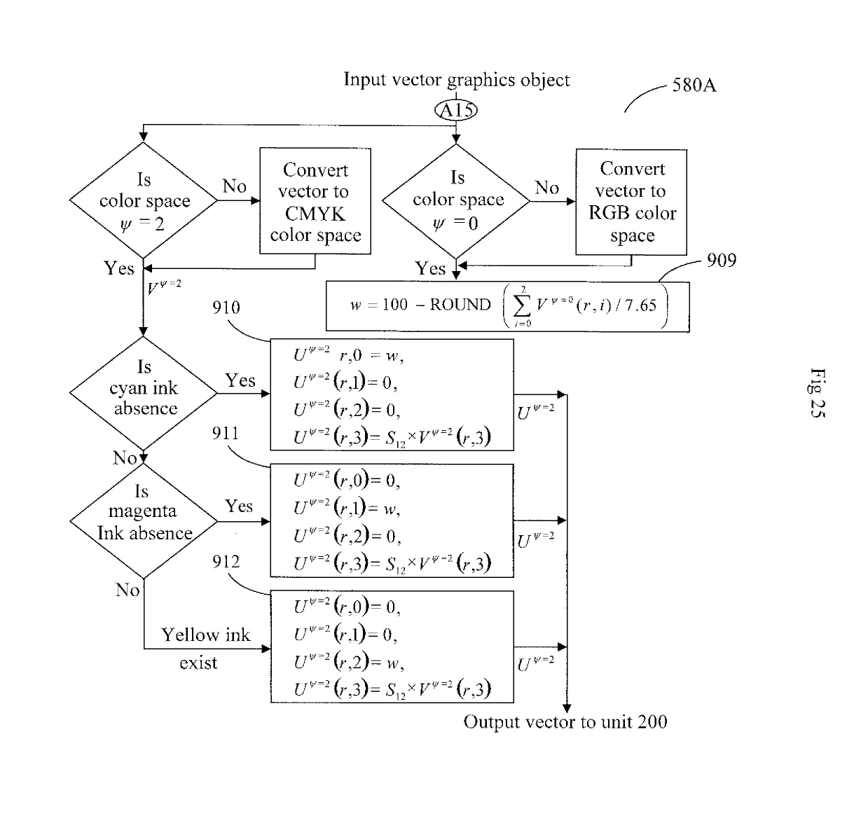

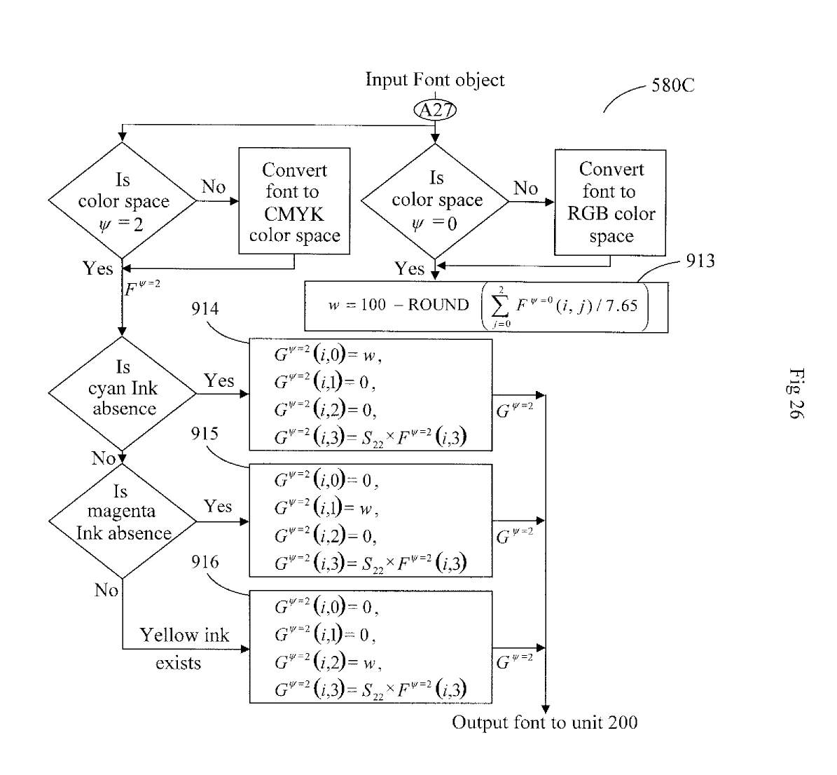

FIGS. 24, 25 and 26 illustrate algorithms which enable ink/toner saving and printing whenever only one of the ink/toner CMY-components is absent. FIG. 24 includes algorithm unit 580 for processing raster graphic; FIG. 25 includes algorithm unit 580A for processing vector graphic; and FIG. 26 includes algorithm unit 580B for processing font objects. In these algorithms the process checks first if the input objects color space is KGB, and if false (no) then it converts the color space to RGB. Referring to FIG. 24 the algorithm includes the step of calculating w by executing unit number 905:

$$w = 100 - ROUND ( {\sum }_{i = 0}^{2} {A}^{ψ = 0} ( x , y , i ) / 7.65 )$$

Next, the process checks if the input objects color space is CMYK, and if false (no) then it converts the color space to CMYK. Then the process checks which of the CMY color component is missing and applies the computed w. In the case or cyan-absence the process executes unit number 906:
B^{ψ=2}(x,y,0)=w,
B^{ψ=2}(x,y1)=0,
B^{ψ=2}(x,y,2)=0,
B^{ψ=2}(x,y,3)=S₀₂×A^{ψ=2}(x,y,3)

In the case of magenta-absence the process executes unit number 907:
B^{ψ=2}(x,y,0)=0,
B^{ψ=2}(x,y,1)=w,
B^{ψ=2}(x,y,2)=0,
B^{ψ=2}(x,y,3)=S₀₂×A^{ψ=2}(x,y,3)

In the case of yellow-absence the process executes unit number 908:
B^{ψ=2}x,y,0=0,
B^{ψ=2}(x,y,1)=0,
B^{ψ=2}(x,y,2)=w,
B^{ψ=2}(x,y,3)=S₀₂×A^{ψ=2}(x,y,3)

Referring to FIG. 25 the algorithm includes the step of calculating MS by executing unit number 909:

$$w = 100 - ROUND ( {\sum }_{i = 0}^{2} {V}^{ψ = 0} ( r , i ) / 7.65 )$$

Next, the process checks if the input objects color space is CMYK, and if false (no) then it converts the color space to CMYK. Then the process checks which of the CMY color component is missing and applies the computed w. In the case of cyan-absence the process executes unit number 910:
U^{ψ=2}r,0=w,
U^{ψ=2}(r,1)=0,
U^{ψ=2}(r,2)=0,
U^{ψ=2}(r,3)=S₁×V^{ψ=2}(r,3)

In the case of magenta-absence the process executes unit number 911:
U^{ψ=2}(r,0)=0,
U^{ψ=2}(r,1)=w,
U^{ψ=2}(r,2)=0,
U^{ψ=2}(r,3)=S₁×V^{ψ=2}(r,3)

In the case of yellow-absence the process executes unit number 912:
U^{ψ=2}(r,0)=0,
U^{ψ=2}(r,1)=0,
U^{ψ=2}(r,2)=w,
U^{ψ=2}(r,3)=S₁×V^{ψ=2}(r,3)

Referring to FIG. 26 the algorithm includes the step of calculating w by executing unit number 913:

$$w = 100 - ROUND ( {\sum }_{j = 0}^{2} {F}^{ψ = 0} ( i , j ) / 7.65 )$$

Next, the process checks if the input objects color space is CMYK, and if false (no) then it converts the color space to CMYK, Then the process checks which of the CMY color component is missing and applies the computed w. In the case of cyan-absence the process executes unit number 914:
G^{ψ=2}(i,0)=w,
G^{ψ=2}(i,1)=0,
G^{ψ=2}(i,2)=0,
G^{ψ=2}(i,3)=S₂₂×F^{ψ=2}(i,3)

In the case of magenta-absence the process executes unit number 915:
G^{ψ=2}(i,0)=0,
G^{ψ=2}(i,1)=w,
G^{ψ=2}(i,2)=0,
G^{ψ=2}(i,3)=S₂₂×F^{ψ=2}(i,3)

In the case of yellow-absence the process executes unit number 916:
G^{ψ=2}(i,0)=0,
G^{ψ=2}(i,1)=0,
G^{ψ=2}(i,2)=w,
G^{ψ=2}(i,3)=S₂₂×F^{ψ=2}(i,3)

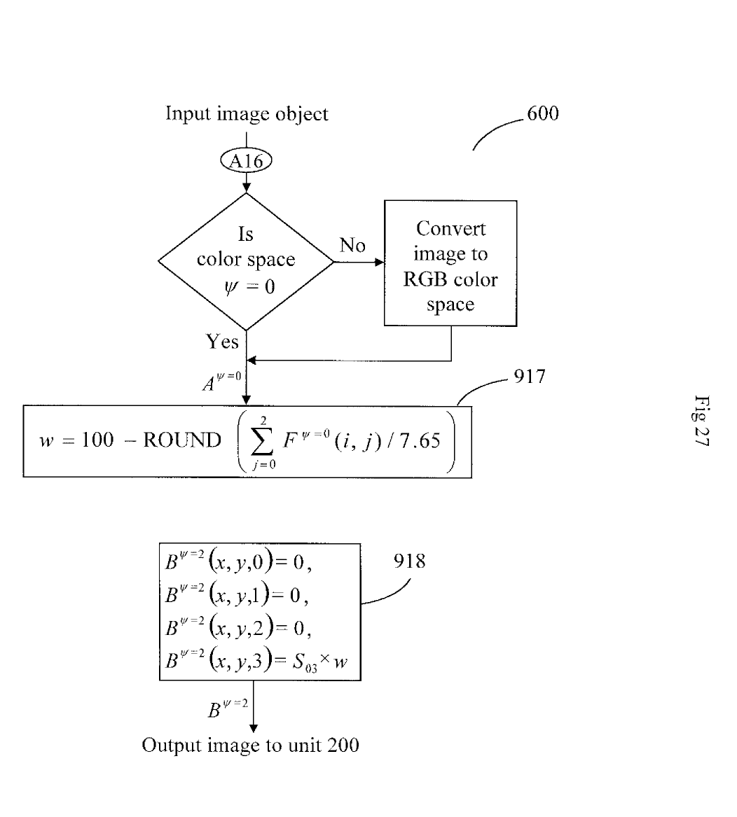

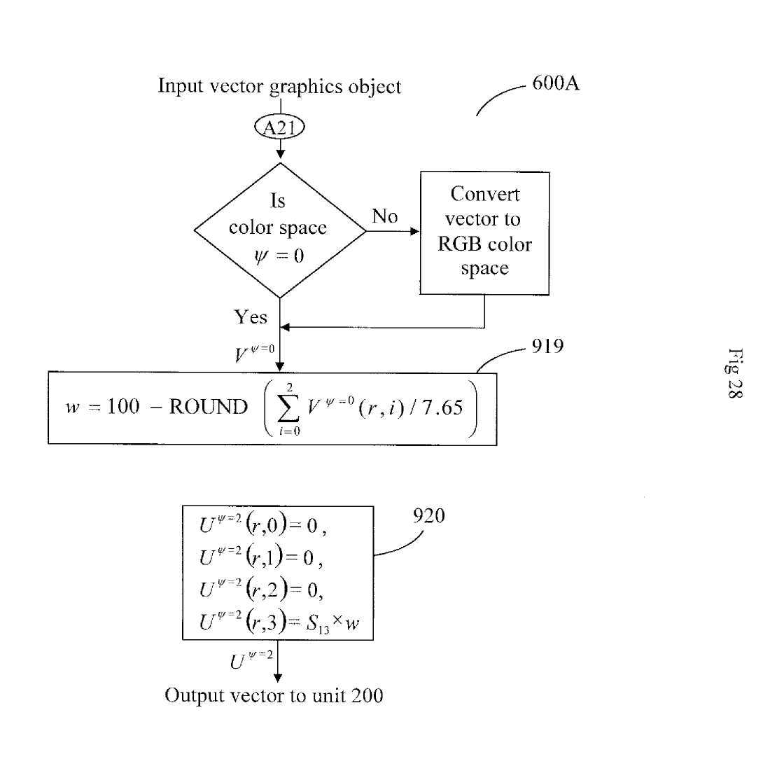

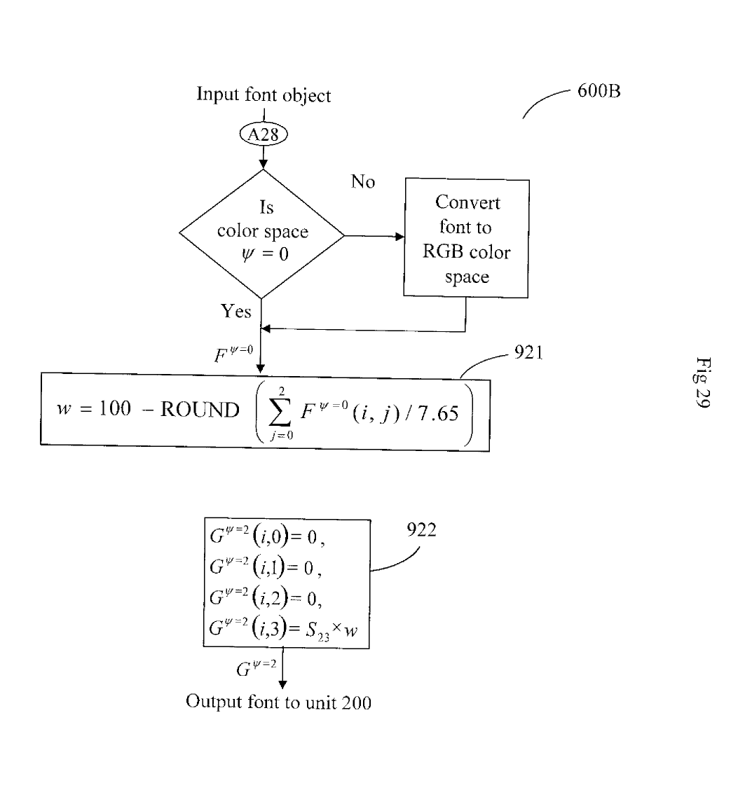

FIGS. 27, 28 and 29 illustrate algorithms which enable ink/toner K-color component saving and printing whenever all CMY-components are absent. FIG. 27 illustrates unit 600 for processing raster graphic; FIG. 28 illustrates unit 600A for processing vector graphic; and FIG. 29 illustrates 600B for processing font objects. In these algorithms the process checks first if the input objects color space is RGB and if false (no) then it converts the color space to RGB. Referring to FIG. 27 the algorithm includes the step of calculating w by executing unit number 917:

$$w = 100 - ROUND ( {\sum }_{j = 0}^{2} {F}^{ψ = 0} ( i , j ) / 7.65 )$$

Next, the process uses the computed w to calculate the output object in unit 918:
B^{ψ=2}(x,y,0)=0,
B^{ψ=2}(x,y,1)=0,
B^{ψ=2}(x,y,2)=0,
B^{ψ=2}(x,y,3)=S₀₃×w

Referring to FIG. 28 the algorithm includes the step of calculating v4, by executing unit number 919:

$$w = 100 - ROUND ( {\sum }_{i = 0}^{2} {V}^{ψ = 0} ( r , i ) / 7.65 )$$

Next, the process uses the computed w to calculate the output object in unit 920:
U^{ψ=2}(r,0)=0,
U^{ψ=2}(r,1)=0,
U^{ψ=2}(r,2)=0,
U^{ψ=2}(r,3)=S₁₃×w

Referring to FIG. 29 the algorithm includes the step of calculating w by executing unit number 921:

$$w = 100 - ROUND ( {\sum }_{j = 0}^{2} {F}^{ψ = 0} ( i , j ) / 7.65 )$$

Next, the process uses the computed w to calculate the output object in unit 922:
G^{ψ=2}(i0)=0,
G^{ψ=2}(i,1)=0,
G^{ψ=2}(i2)=0,
G^{ψ=2}(i,3)=S₂₃×w

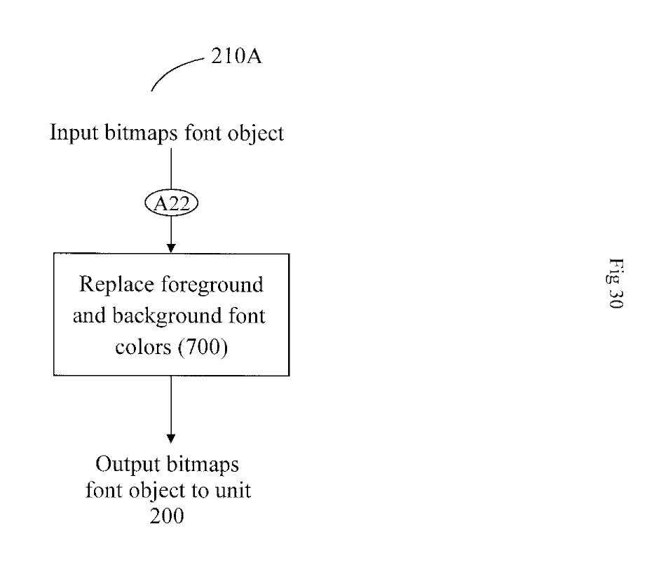

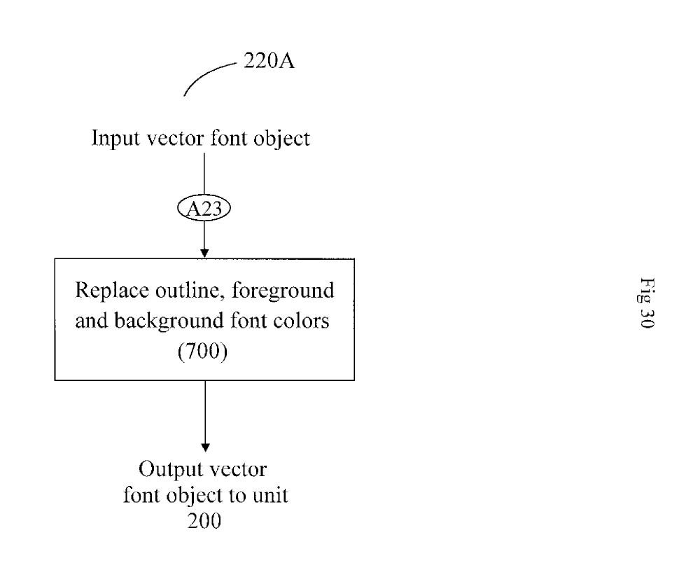

FIG. 30 is an illustration of the algorithm for replacing colors of bitmap fonts for saving and balancing their foreground and background colors. Algorithm 210A includes unit 700 which performs the replacement. FIG. 31 is an illustration of the algorithm for replacing colors of vector fonts for saving and balancing their foreground and background colors. Algorithm 220A includes unit 700 which performs the replacement. This procedure may also include processing the outline colors, provided that the printer device 60 enables it.

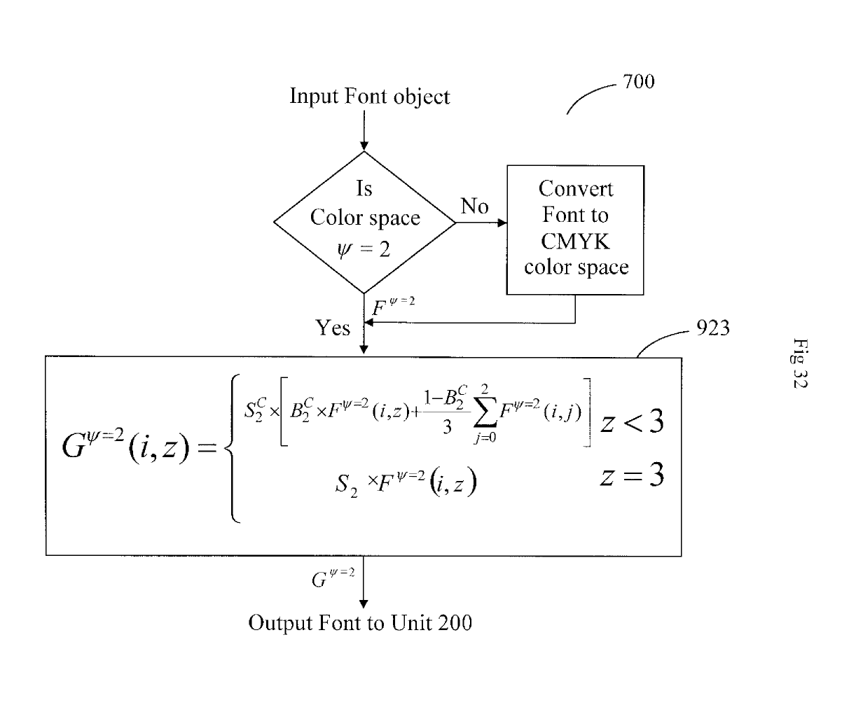

FIG. 32 illustrates the algorithm for saving and balancing ink/toner colors in font objects. In units 700 the algorithm first checks if the input objects color space is CMYK, and if false (no) then it converts the color space to CMYK. Then the output font colors are calculated using unit number 923:

$${G}^{ψ = 2} ( i , z ) = \{ \begin{matrix}{S}_{2}^{C} \times [ {B}_{2}^{C} \times {F}^{ψ = 2} ( i , z ) + \frac{1 - {B}_{2}^{C}}{3} {\sum }_{j = 0}^{2} {F}^{ψ = 2} ( i , j ) ] & z < 3 \\ {S}_{2}^{x} {F}^{ψ = 2} ( i , z ) & z = 3\end{matrix}$$

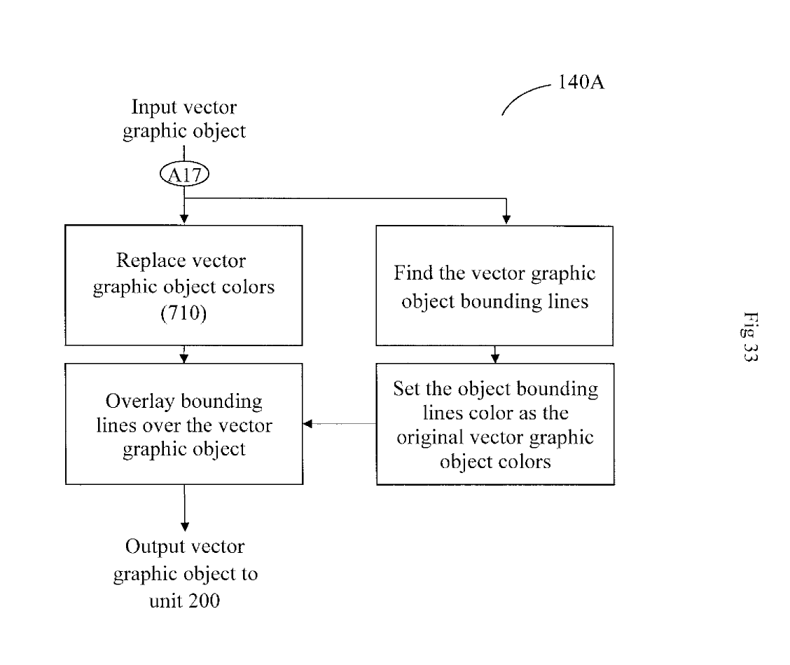

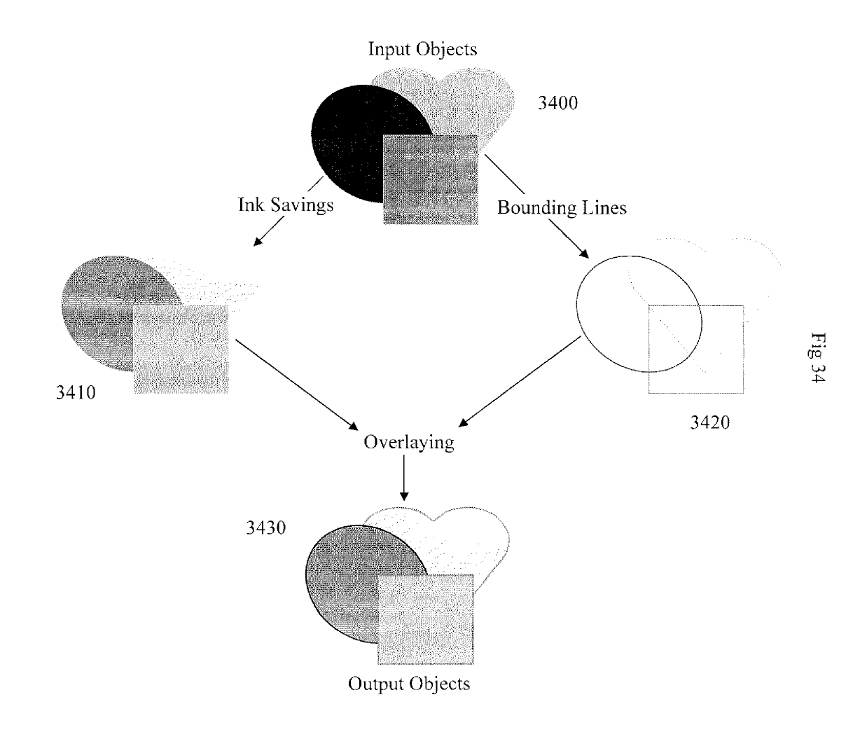

FIG. 33 illustrates the algorithm for performing the replacement of colors of vector graphic objects for saving and balancing their colors. In unit 140 the algorithm finds the boundary lines of the objects and set their colors as the original object colors. The boundary lines are overlaid over the processed objects. FIG. 34 is a graphic illustration of the process of finding the boundary lines of the objects and setting their colors as the original object colors. The original objects 3400 are processed by the ink saving algorithm which replaces their original colors with the processed colors to produce objects 3410. The algorithm also identifies the boundary lines of the objects and sets them to their original color 3420. Finally, the boundary line 3420 are laid over processed objects 3410 to produce the final output objects 3430.

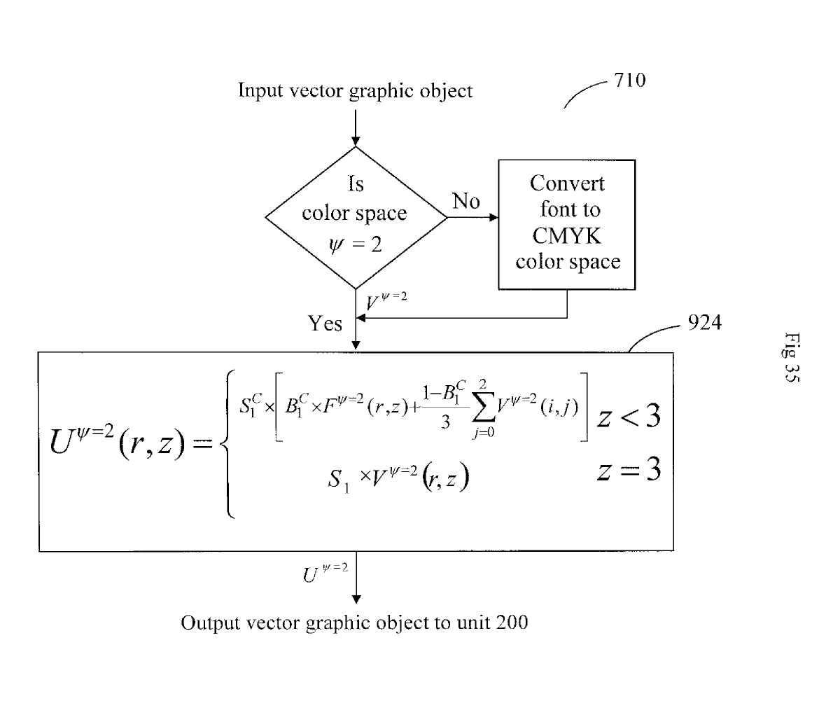

FIG. 35 is an illustration of the algorithm for saving and balancing ink/toner colors in vector graphic objects. In this algorithm the process of unit 710 first checks if the input objects color space is CMYK, and if false (no) then it converts the color space to CMYK. Then the output vector graphic object colors are calculated using unit number 924:

$${U}^{ψ = 2} ( r , z ) = \{ \begin{matrix}{S}_{1}^{C} \times [ {B}_{1}^{C} \times {F}^{ψ = 2} ( r , z ) + \frac{1 - {B}_{1}^{C}}{3} {\sum }_{j = 0}^{2} {V}^{ψ = 2} ( i , j ) ] & z < 3 \\ {S}_{1}^{x} {V}^{ψ = 2} ( r , z ) & z = 3\end{matrix}$$

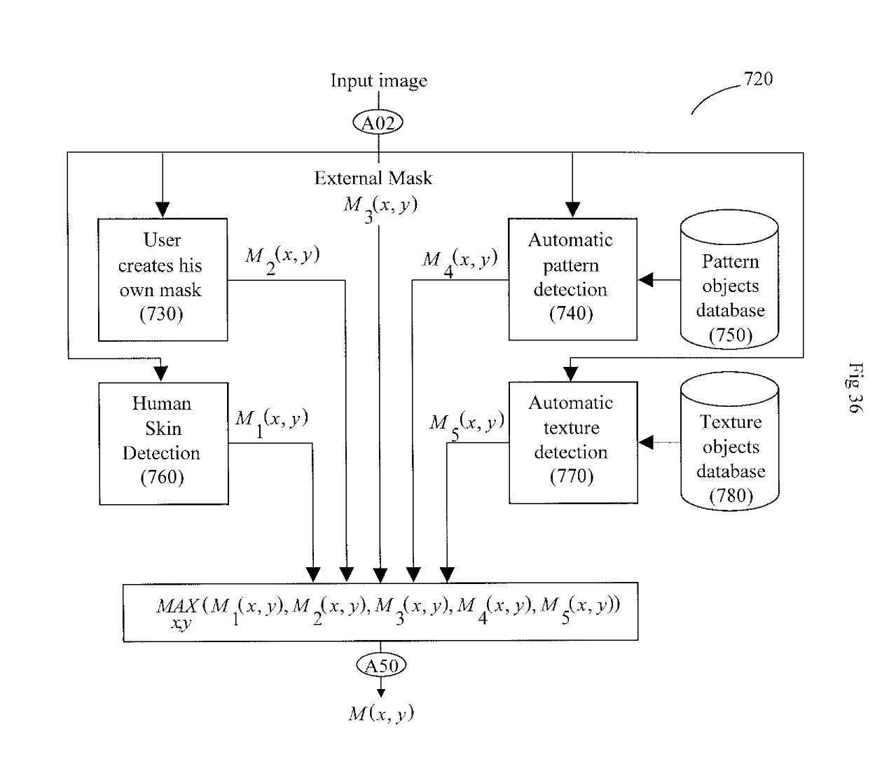

FIG. 36 illustrates the algorithm for mask M(i, j) calculations. Masks Mₙ(i, j) performed on input A02 saving-balancing image operations refers to enforcing pixels data processing exclusion in contained areas. Assuming that there is a certain area of interest, that the user wishes to preserve as-is, in the pixels data input A02 image, then either a masks Mₙ(i, j) obtained from units 730, 740, 760 and 770, are accessed by the ink/toner saving-balancing system and excluded. Alternatively, the given area is optionally treated by the saving-balancing system operations. The following are a detailed description of ink/toner stage unit 720 in the saving-balancing system:

Unit 730—users create their own mask M₂(i, j) at run, using inherent editing selection tool supplied by the saving-balancing system.

Unit 740—the saving-balancing system calls the supplied database-patterns in unit 750, which contains pattern objects (e.g. logo, car, chair). Unit 740 then carries out a process of CV pattern recognition using approximate identification pattern detection techniques of the desired patterned-objects immerged within A02 input image. The mask pixel values correspond to the matching power of every pattern in the database to the input image. For example, in the “matched filtering” based recognition algorithms the matching power is the correlation image.

Unit 760—a mask is prepared using human-skin recognition techniques. The values of the m-ask pixels correspond to the statistical probability that input image pixel belong to human skin region.

Unit 770—the saving-balancing system calls the supplied database-textures of unit 780, which contains texture samples (e.g. fabric, wallpaper, nature landscape). Unit 770 then carries out a process of CV texture recognition using techniques of the desired texture sample immerged within A02 input image. The mask pixel values correspond to the matching power of every texture in the database to the input image.

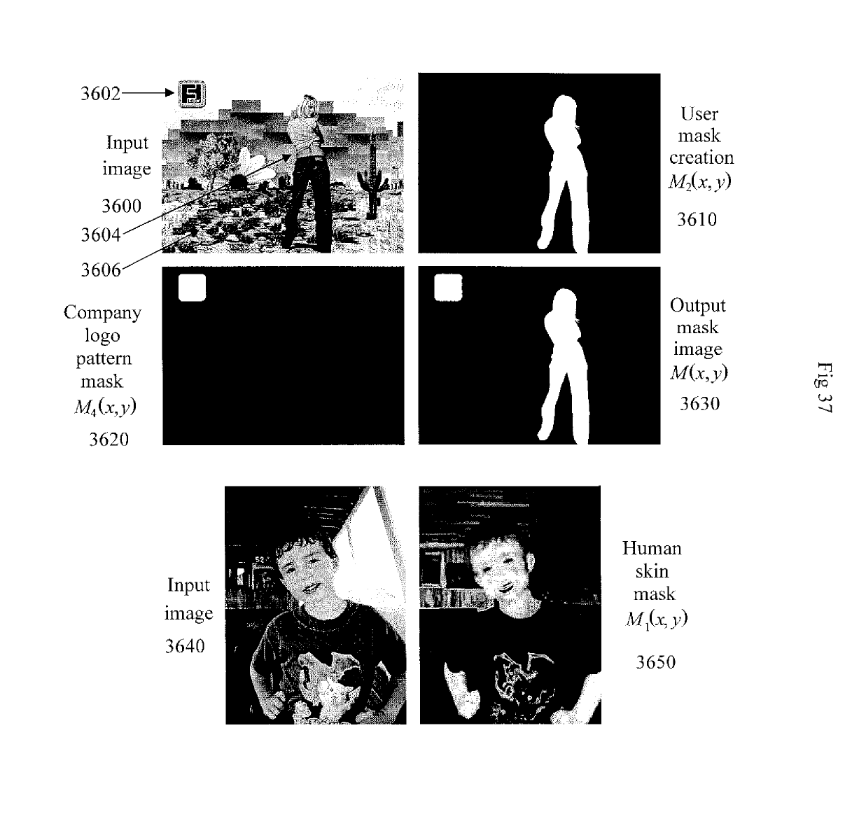

FIG. 37 is an example for the processes performed by unit 720. Image input 3600 contains a company logo 3602, an image of a person 3604 and a background 3606. The company logo 3602 and the image of the person 3604 are defined as regions of interest. Through unit 730 the user manually creates a mask of the figure of the person 3604 resulting in mask 3610. Unit 740 automatically creates a mask for the company logo 3602 resulting in mask 3620. The output mask 3630 is the combination of masks 3610 and 3620, masking both the logo of the company 3602 and the image of the person 3604. Similarly, in processing input image 3640, unit 760 creates a mask of human skin recognition resulting in human skin mask 3650.

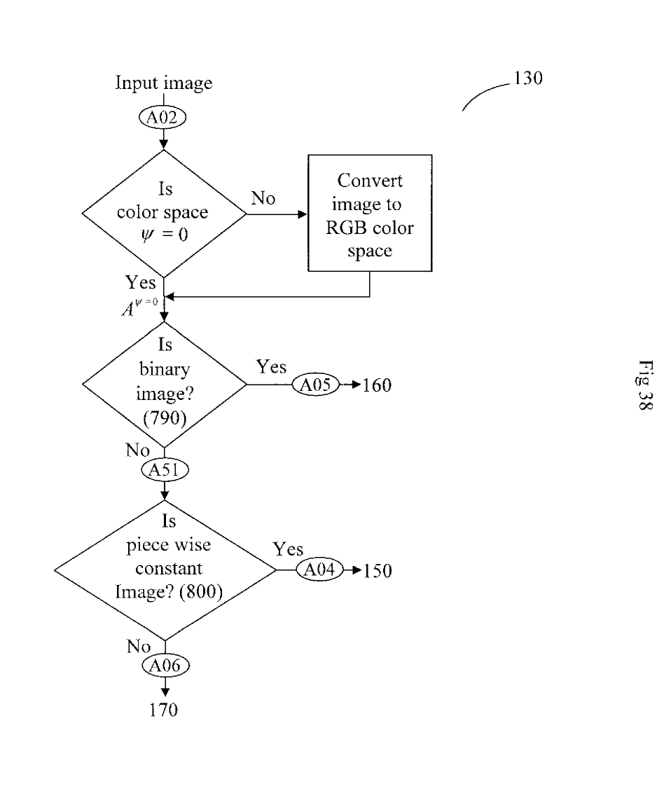

FIG. 38 is an illustration of the algorithm for the classification of raster images to the classes of binary images, piecewise constant images or photo images. In this algorithm of unit 130 the process first checks if the input objects color space is KGB, and if false (no) then it converts the color space to KGB. Then unit 790 checks whether the input image is a binary image one and if true (yes) then unit 160 is executed. Otherwise, the algorithm continues the process of classification. Unit 800 checks if the input image is a piecewise constant image. If the answer is true (yes) then unit number 150 is processed, and if false (no) then the input image is classified as photo image and the process continues to unit number 170.

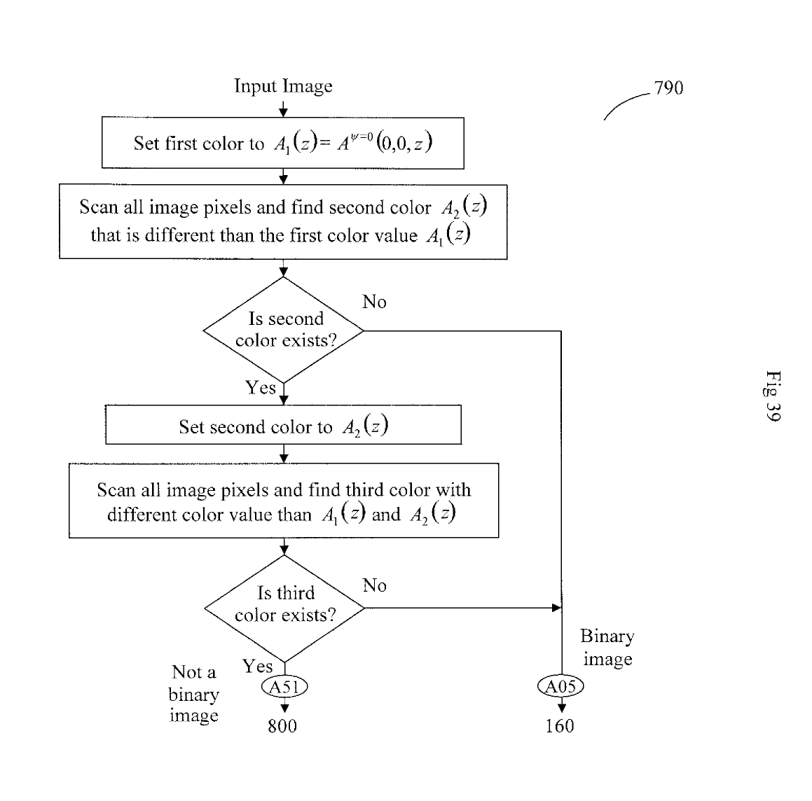

FIG. 39 is an illustration of the algorithm for checking whether the input raster image is a binary one. The algorithm of unit 790 set the first color value A₁(z) from the input image in pixel located at (0, 0), where z is the image color channel in RGB color space. Then the algorithm scans all image pixels and finds second color A₂(z) having a value which is not A₁(z). If the algorithm cannot find a second color value A₂(z) it continues to unit 160. If the algorithm finds a second color value A₂(z) then it scans all image pixels for a third color A₃(z) having different value than A₁(z) and A₂(z). If the algorithm cannot find a third color value A₃(z) it continues to unit 160. Otherwise it is not a binary image and it continues to unit number 800.

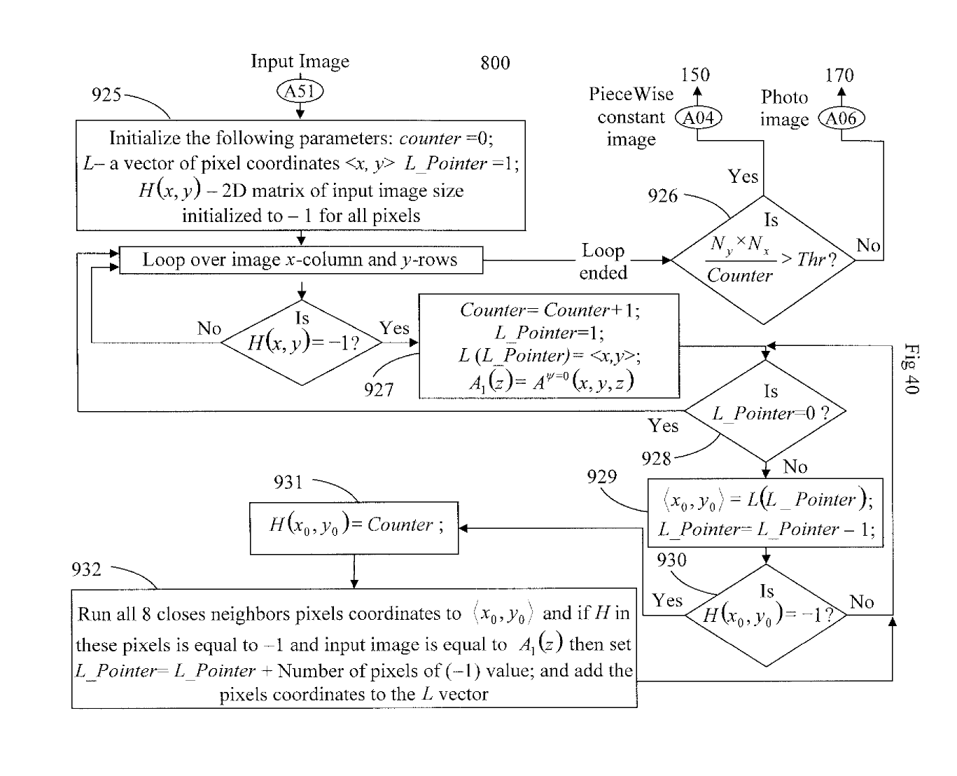

FIG. 40 is an illustration of the algorithm for checking whether the input raster image is either a piecewise image or a photo image. First, the algorithm of unit 800 initializes the needed parameters and variables in unit 925. The parameters include a counter, which is used to count constant-color-value in image regions, and a dynamic vector of pixel coordinates L and 2D image H(x, y) of size of the input image that is initialized to −1 value to all pixels. The algorithm scans all image pixels successively, and performs the following procedure for each pixel:

If the pixel satisfies H(x, y)=−1 then the procedure continues to unit 927, else the next pixel is scanned. Next, unit 927 is executed. In this unit the pixel coordinates <x,y> are added to L vector, its color value is passed to A₁(z), the pointer of L is initialized to 1, and the counter is incremented by 1. Then unit 926 checks if the pointer equals zero. If the answer is true (yes) then the procedure is terminated and the next pixal is scanned, otherwise, the procedure continues to unit 929. Unit 929 passes the coordinates in vector L, to the variable <x₀,y₀>, and the pointer is retracted by a single position. Next, unit 930 checks if H(x₀,y₀)=−1. If true (yes) the process continues to unit 931, otherwise (false) it returns to unit 928. Unit 931 passes the value of the counter to H(x₀,y₀) and the process continues to unit 932 and then returns to unit 928. In unit 932 the process runs all eight pixels in the proximity of coordinates <x₀,y₀) and if H in these pixels is equal to −1 and also the input image is equal to A₁(z), then the process increment the pointer by the number of pixels having (−1) value, and then adds the pixels coordinates to the L vector.

Once the input image scanning is finalized, unit 926 is executed. This unit determines the ratio of image size divided by the value of the counter. The counter value corresponds to the number of constant-color-value areas. If the ratio is larger than a predetermined threshold Thr, then the image is classified as piecewise-constant-image, otherwise, the input image is classified as photo.

FIG. 40 is an illustration of the algorithm for the processing of piecewise constant image objects, for carrying out ink/toner saving and balancing. In this algorithm of unit 150A the process first checks if the input objects color space is CMYK, and if false (no) then it converts the color space to CMYK. Then the process executes unit 933. In unit 933 conventional edges extraction operation is applied on H(x, y) image obtained from unit 800. The edges-image is converted to a binary image in unit 934 by setting pixels of values other than zero to one. The algorithm assumes that edges-image is equal to zero in regions of constant values. The output binary image h^{b}(x, y) of unit 934 receives the value of 1 on outline boundaries and 0 in all other cases. The algorithm is aimed to preserve boundary original color values of the original image at the output image. In cases of maximum ink/toner saving (S₀₀^{CMY}=0 or S₀₁^{CMY}=0) the output image will still preserve image information by keeping the outline contours while removing the monotonic regions. The binary image H^{B}(x, y) and the mask image M(x, y) from unit 720 are combined in unit 935. The output image H^{M}(x, y) from unit 935 and the input image in CMYK color space are used to produce the output image in unit 936:

$$\begin{matrix}{B}^{ψ = 2} ( x , y , z ) = {{H}^{M} ( x , y )}^{x} {A}^{ψ = 2} ( x , y , z ) + {[ 1 - {H}^{M} ( x , y ) ]}^{x} \\ \{ \begin{matrix}{S}_{0}^{C} \times [ {B}_{1}^{C} \times {A}^{ψ = 2} ( x , y , z ) + \frac{1 - {B}_{0}^{C}}{3} {\sum }_{j = 0}^{2} {A}^{ψ = 2} ( x , y , j ) ] & z < 3 \\ {S}_{0}^{x} {A}^{ψ = 2} ( x , y , z ) & z = 3\end{matrix}\end{matrix}$$

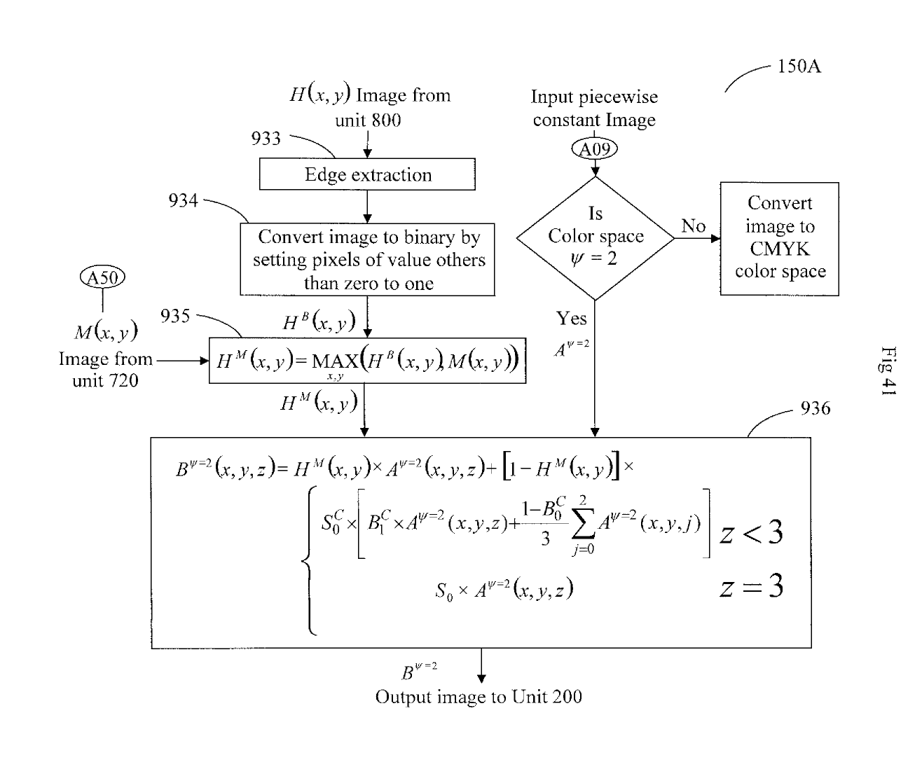

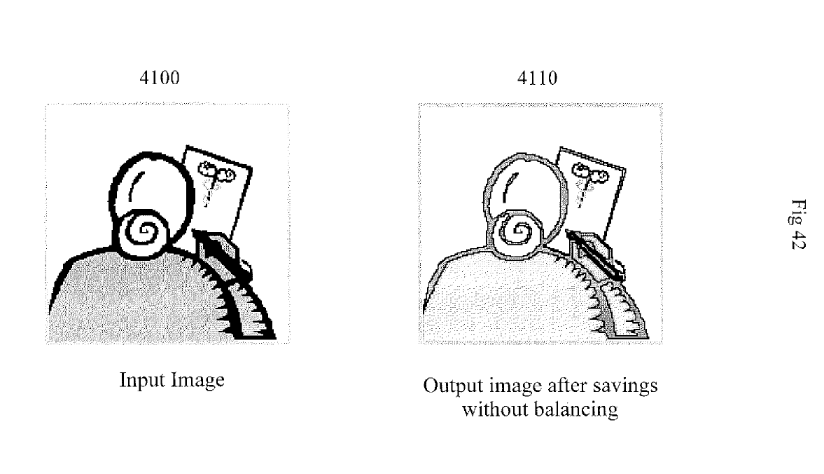

FIG. 41 is an exemplary illustration of the above described procedure. Image 4100 represents an original input image. Image 4110 is the output image after being processed by unit 150A FIG. 42 is an illustration of the algorithm for the processing of binary image objects, for carrying out ink/toner saving and balancing. In this algorithm of unit 160A the process checks first if the input objects color space is CMYK, and if false (no) then it converts the color space to CMYK. The input binary image in CMYK color space and the mask image M(x, y) from unit 720 are used to produce the output image in unit 937:

$$\begin{matrix}{B}^{ψ = 2} ( x , y , z ) = {M ( x , y )}^{x} {A}^{ψ = 2} ( x , y , z ) + {[ 1 - M ( x , y ) ]}^{x} \\ \{ \begin{matrix}{S}_{0}^{C} \times [ {B}_{0}^{C} \times {A}^{ψ = 2} ( x , y , z ) + \frac{1 - {B}_{0}^{C}}{3} {\sum }_{j = 0}^{2} {A}^{ψ = 2} ( x , y , j ) ] & z < 3 \\ {S}_{0}^{x} {A}^{ψ = 2} ( x , y , z ) & z = 3\end{matrix}\end{matrix}$$

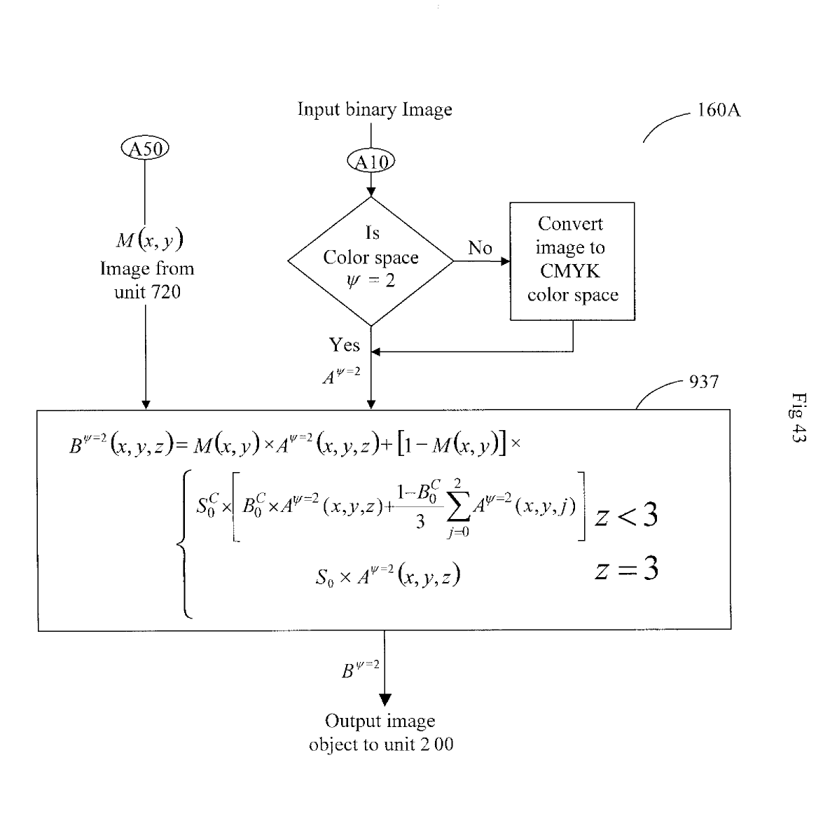

FIG. 43 is an illustration of the algorithm for the processing of photo image objects, for carrying out ink/toner saving and balancing. In this algorithm of unit 170A the process checks first if the input objects color space is CMYK, and if false (no) then it converts the color space to CMYK

Next, three weights' images Mₐ(x, y), M_{b}(x, y), M_{c}(x, y) are calculated in unit 810, where images' values are greater or equal to zero:

$$Se$$

$$μ ( z ) = \frac{1}{{N}_{x}^{x} {N}_{y}} {\sum }_{x = 1}^{{N}_{x}} {\sum }_{y = 1}^{{N}_{y}} {A}^{ψ = 2} ( x , y , z ) 0 \leq z \leq 2$$

$$\overline{μ} = \frac{1}{3} {\sum }_{z = 0}^{2} μ ( z )$$

$${M}_{a} ( x , y ) = {f}_{1} ( {A}^{ψ = 2} ( x , y , 3 ) , {B}_{0}^{C} )$$

$${M}_{b} ( x , y ) = {f}_{2} ( {A}^{ψ = 2} ( x , y , 3 ) , {S}_{0}^{C} )$$

$${M}_{c} ( x , y ) = {f}_{3} ( {A}^{ψ = 2} ( x , y , 3 ) , {S}_{0} )$$

The function f₁, receives as the input parameters A^{ψ=2}(x, y,3), B₀^{C}. The parameter A^{ψ=2}(x, y,3) is the K component of the input image and B₀^{C} parameter is the balancing power that is set at the beginning of the process by the user. In general terms, f₁ holds for any function that maintain Mₐ(x, y) to be proportional to B₀^{C} and inversely proportional to A^{ψ=2}(x, y, 3).

M_{b}(x, y) image corresponds to CMY ink/toner saving weights, it is calculated by function f₂, which receives as the input parameters A^{ψ=2}(x, y, 3), S₀^{C}. The parameter A^{ψ=2}(x, y, 3) is the K component of the input image and S₀^{C} parameter is the CMY-saving power that is set at the beginning of the process by the user. In general terms, f₂ holds for any function that maintain M_{b}(x, y) to be proportional to S₀^{C} and inversely proportional to A^{ψ=2}(x, y, 3).

M_{c}(x, y) image corresponds to K ink/toner saving weights, it is calculated by function f₃, which receives as input parameters A^{ψ=2}(x, y, 3), S₀. Parameter A^{ψ=2}(x, y, 3) is the K component of the input image and S₀ parameter is the K-saving power that is set at the beginning of the process by the user. In general terms, f₃ holds for ally function that maintains M_{c}(x, y) to be proportional to S₀ and inversely proportional to A̅^{ψ=2}(x, y,3), where A̅ is the derivates image of 100−A^{ψ=2}(x, y, 3), after zeroing negative values. This process is based on the bordering effect, explained below.

Next, the algorithm calculates image Â in unit number 820 using the Mₐ(x, y), M_{b}(x, y), M_{c}(x, y) for saving and balancing:

$${\hat{A}}^{ψ = 2} ( x , y , z ) = \{ \begin{matrix}{M}_{b}^{x} [ {A}^{ψ = 2} ( x , y , z + {M}_{a}^{x} ( \overline{μ} - μ ( z ) ) ] & z < 3 \\ {M}_{c}^{x} {A}^{ψ = 2} ( x , y , z ) & z = 3\end{matrix}$$

Then, unit 830 calculates image Â from image Â by applying an appropriate f₄ function. Function f₄ is limiting the values of Â in the range [0, 1001]:
\hat{Â}^{ψ=2}(x,y,z)=f₄(Â^{ψ=2}(x,y,z))

Finally, the algorithm calculates the output image B in unit number 840:
B^{ψ=2}(x,y,z)=M(x,y)^{×}A^{ψ=2}(x,y,z)+[1−M(x,y)]^{×}\hat{Â}^{ψ=2}(x,y,z)

In this unit the mask image M(x, y) is implemented for the purpose of preserving image quality level in important or selected regions.

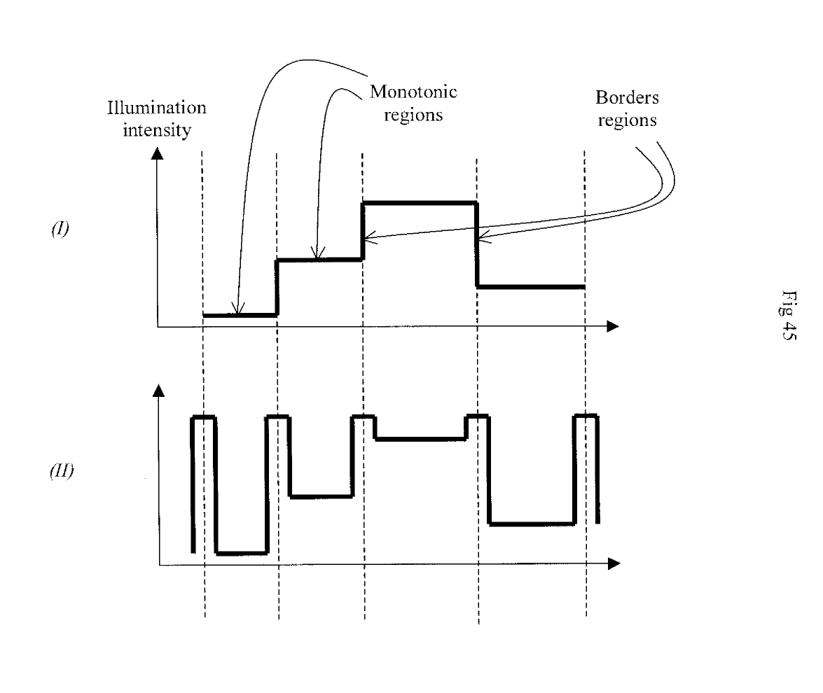

FIG. 45 is an illustration of the scheme of bordering effect. Any image can be viewed as a composition of monotonic and border areas. In human perception the monotonic regions are perceived as darker than they really are if the illumination levels at the border regions are increased. FIG. 45 shows one-dimension cross-section illumination intensity graphs of an image. (I) is the graph of the original image and (II) is the graph of image after increasing illumination in border regions.

While the invention has been described with respect to a limited number of embodiments, these should not be construed as limitations on the scope of the invention, but rather as exemplifications of some of the embodiments. Those skilled in the art will envision other possible variations, modifications, and applications that are also within the scope of the invention. Accordingly, the scope of the invention should not be limited by what has thus far been described, but by the appended claims and their legal equivalents. Therefore, it is to be understood that alternatives, modifications, and variations of the present invention are to be construed as being within the scope and spirit of the appended claims.

What is claimed is:

1. A method for saving colorant particles of a printing device during a printing procedure of a document, said method comprising the steps of:
identifying segments of said document according to object types;
processing each object type of document in accordance with the object attributes and identified characteristics of said object;
adjusting said processing in accordance with Computer Vision (CV) and image processing techniques of filtering modules;
applying transformation of printing color characteristics on at least one object in said document, wherein the transformation is applied in accordance with predefined rules and identified characteristics of each object.

2. The method of claim 1 further comprising the step of tracking usage of colorant and balancing their consumption at lined-out level for reaching maximum parallel utilization.

3. The method of claim 1 further comprising the steps of:
checking availability of colorants in said printing device;
using existing colorants to fill-in for missing colorants.

4. The method of claim 1 wherein said object types include at least one of the following: binary images, piecewise-constant images, photograph images, vector graphic, vector font, bitmaps font.

5. The method of claim 1 further comprising the step of converting grayscale segments of said document from colorants to black pigments using grey component replacement (GCR) methods.

6. The method of claim 5 wherein said GCR method is within the range between maximum GCR and non-GCR methods.

7. The method of claim 1 further comprising the step of performing at least one of the following procedures: adoptive separation procedures differential colorants saving procedure in said document applying CV and image processing generated modules.

8. The method of claim 1 wherein said procedure is performed by identifying regions of interest (ROI) further comprising the step of applying masking methods on segments in said document.

9. The method of claim 8 wherein said identification is preformed according to predefined classification of the attributes of regions within said document.

10. The method of claim 8 wherein said identification is performed by distinguishing between image and background sections in said document;

11. The method of claim 8 wherein said identification is performed by identifying preferred objects in said document.

12. The method of claim 8 further comprising the step of applying colorant saving techniques to segments of said document which are outside of said ROI.

13. The method of claim 8 wherein said identification between sections is performed automatically.

14. The method of claim 8 wherein said distinction between sections is performed according to user preferences as defined by the user using a graphic user interface (GUI).

15. The method of claim 1 further comprising the step of utilizing a dedicated color perception process based on bordering effect which maintains visual intensity perception in response to illumination.

16. The method of claim 1 wherein said method is applied with respect to the various hues of the component colors.

17. The method of claim 1 further comprising the steps of
evaluating levels of K-component in comparison to CMY-components in regions which combine K-component and CMY-components;
reducing CMY consumption when K-component levels are dominant.

18. The method of claim 17 further comprising the step of selecting adaptive proportional linear K-consumption with respect to the original component-level and compressing the CMY color channel according to their hues using varying quantization levels per pixel.

19. The method of claim 1 wherein said method is implemented in an independent hardware component.

20. The method of claim 1 wherein said method is implemented as a software component.
